(19) United States
(12) Patent Application Publication
(10) Pub. No.: US 2022/0414940 A1
(43) Pub. Date: Dec. 29, 2022

(54) INFORMATION PROCESSING APPARATUS AND METHOD

(71) Applicant: SONY GROUP CORPORATION, Tokyo (JP)

(72) Inventors: Hiroyuki YASUDA, Saitama (JP); Ohji NAKAGAMI, Tokyo (JP); Tsuyoshi KATO, Kanagawa (JP); Koji YANO, Tokyo (JP); Satoru KUMA, Tokyo (JP)

(73) Assignee: SONY GROUP CORPORATION, Tokyo (JP)

(21) Appl. No.: 17/762,995

(22) PCT Filed: Sep. 17, 2020
(86) PCT No.: PCT/JP2020/035206

§ 371 Date: Mar. 23, 2022

(30) Foreign Application Priority Data
Oct. 1, 2019 (JP) 2019-181401

(51) Int. Cl. G06T 9/00; G06T 9/40

(52) U.S. Cl. CPC G06T 9/001; G06T 9/40

(57) ABSTRACT

The present disclosure relates to an information processing apparatus and a method capable of controlling the number of the points to be obtained by decoding. A bitstream is generated, the bitstream including encoded data of 3D data having a plane expressing points in a point cloud that expresses a three-dimensional object as a set of the points, and control information for controlling the number of the points to be derived from the 3D data to be obtained by decoding the encoded data. The present disclosure can be applied to an information processing apparatus, an image processing apparatus, an encoding device, a decoding device, an electronic apparatus, an information processing method, a program, or the like, for example.

### TECHNICAL FIELD

The present disclosure relates to information processing apparatuses and methods, and more particularly, to an information processing apparatus and a method that are designed to be capable of controlling the number of the points in the point cloud to be obtained by decoding.

### BACKGROUND ART

Encoding and decoding of point cloud data expressing a three-dimensional object as a set of points has been standardized by Moving Picture Experts Group (MPEG) (see Non-Patent Document 1, for example). Also, in encoding of the point cloud data, a method called “trisoup” in which points in a voxel are expressed by a triangular plane has been conceived. Further, in decoding the points in a voxel to decode encoded data to which the trisoup is applied, a method has been suggested for setting the points at the intersections with vectors parallel to a triangular plane in three axial directions (see Non-Patent Document 2, for example).

### CITATION LIST

### Non-Patent Documents

Non-Patent Document 1: “Information technology—MPEG-I (Coded Representation of Immersive Media)—Part 9: Geometry-based Point Cloud Compression”, ISO/IEC 23090-9: 2019(E)
Non-Patent Document 2: Ohji Nakagami, “PCC On Trisoup decode in G-PCC”, ISO/IEC JTC1/SC29/WG11 MPEG2018/m44706, October 2018, Macao, CN

### SUMMARY OF THE INVENTION

### Problems to be Solved by the Invention

However, in the conventional trisoup, the number of the points in the point cloud to be obtained by decoding cannot be controlled during encoding.

The present disclosure is made in view of such circumstances, and aims to be able to control the number of the points in a point cloud to be obtained by decoding the encoded data thereof, when the points in the point cloud are expressed as a plane and are encoded.

### Solutions to Problems

An information processing apparatus according to one aspect of the present technology is an information processing apparatus that includes a generation unit that generates a bitstream that includes encoded data of 3D data having a plane expressing points in a point cloud that expresses a three-dimensional object as a set of the points, and control information for controlling the number of the points to be derived from the 3D data to be obtained by decoding the encoded data.

An information processing method according to one aspect of the present technology is an information processing method that includes generating a bitstream that includes encoded data of 3D data having a plane expressing points in a point cloud that expresses a three-dimensional object as a set of the points, and control information for controlling the number of the points to be derived from the 3D data to be obtained by decoding the encoded data.

An information processing apparatus according to another aspect of the present technology is an information processing apparatus that includes: a decoding unit that decodes a bitstream, to generate 3D data having a plane expressing points in a point cloud that expresses a three-dimensional object as a set of the points, and control information for controlling the number of the points to be derived from the 3D data; and a derivation unit that derives the points from the 3D data, on the basis of the control information.

An information processing method according to another aspect of the present technology is an information processing method that includes: decoding a bitstream, to generate 3D data having a plane expressing points in a point cloud that expresses a three-dimensional object as a set of the points, and control information for controlling the number of the points to be derived from the 3D data; and deriving the points from the 3D data, on the basis of the control information.

In the information processing apparatus and the method according to one aspect of the present technology, a bitstream is generated, the bitstream including encoded data of 3D data having a plane expressing the points in a point cloud that expresses a three-dimensional object as a set of points, and control information for controlling the number of the points to be derived from the 3D data to be obtained by decoding the encoded data.

In the information processing apparatus and the method according to another aspect of the present technology, a bitstream is decoded to generate 3D data having a plane expressing the points in a point cloud that expresses a three-dimensional object as a set of points, and control information for controlling the number of the points to be derived from the 3D data. Also, the points are derived from the 3D data, on the basis of the control information.

### BRIEF DESCRIPTION OF DRAWINGS

FIG. 1 is a diagram for explaining the outline of a conventional trisoup.

FIG. 2 is a diagram for explaining an example of sampling interval control.

FIG. 3 is a diagram showing an example of limitation on the number of points by level.

FIG. 4 is a chart showing a typical example configuration of a bitstream.

FIG. 5 is a diagram for explaining slices.

FIG. 6 is a chart showing an example syntax.

FIG. 7 is a chart showing an example syntax.

FIG. 8 is a diagram for explaining an example of control on the number of points.

FIG. 9 is a chart showing an example syntax.

FIG. 10 is a diagram for explaining an example of control on the number of points.

FIG. 11 is a diagram for explaining an example of control on the number of points.

FIG. 12 is a diagram for explaining an example of control on the number of points.

FIG. 13 is a diagram for explaining an example of control on the number of points.

FIG. 14 is a chart showing an example syntax.

FIG. 15 is a chart showing an example syntax.

FIG. 16 is a block diagram showing a typical example configuration of an encoding device.

FIG. 17 is a block diagram showing a typical example configuration of a point generation unit.

FIG. 18 is a flowchart for explaining an example flow in an encoding process.

FIG. 19 is a flowchart for explaining an example flow in a point generation process.

FIG. 20 is a block diagram showing a typical example configuration of an encoding device.

FIG. 21 is a block diagram showing a typical example configuration of a point generation unit.

FIG. 22 is a flowchart for explaining an example flow in a decoding process.

FIG. 23 is a flowchart for explaining an example flow in a point generation process.

FIG. 24 is a flowchart for explaining an example flow in a point generation process.

FIG. 25 is a block diagram showing a typical example configuration of a computer.

### MODES FOR CARRYING OUT THE INVENTION

The following is a description of modes for carrying out the present disclosure (the modes will be hereinafter referred to as embodiments). Note that explanation will be made in the following order.

1. Trisoup point number control

2. First embodiment (an encoding device)

3. Second embodiment (a decoding device)

4. Third embodiment (another example of a point generation process)

5. Notes

### 1. TRISOUP POINT NUMBER CONTROL

<Documents and the Like that Support Technical Contents and Terms>

The scope disclosed in the present technology includes not only the contents disclosed in the embodiments, but also the contents disclosed in the following non-patent documents that were known at the time of filing, the contents of other documents referred to in the non-patent documents listed below, and the like.
Non-Patent Document 1: (mentioned above)
Non-Patent Document 2: (mentioned above)

That is, the contents described in the above non-patent documents, the contents of other documents referred to in the above non-patent documents, and the like are also grounds for determining the support requirements.

<Point Cloud>

There has been 3D data such as point clouds that represent three-dimensional structures with positional information, attribute information, and the like about points, and meshes that are formed with vertices, edges, and planes, and define three-dimensional shapes using polygonal representations.

For example, in the case of a point cloud, a three-dimensional structure (a three-dimensional object) is expressed as a set of a large number of points. The data of a point cloud (also referred to as point cloud data) includes positional information (also referred to as geometry data) and attribute information (also referred to as attribute data) about the respective points in this point cloud. The attribute data can include any information. For example, color information, reflectance information, normal information, and the like regarding the respective points may be included in the attribute data. As described above, the data structure of point cloud data is relatively simple, and any desired three-dimensional structure can be expressed with a sufficiently high accuracy with the use of a sufficiently large number of points.

<Quantization of Positional Information Using Voxels>

Since the data amount of such point cloud data is relatively large, an encoding method using voxels has been suggested to reduce the data amount by encoding and the like. A voxel is a three-dimensional region for quantizing geometry data (positional information).

That is, a three-dimensional region containing a point cloud is divided into small three-dimensional regions called voxels, and each voxel indicates whether or not points are contained therein. With this arrangement, the position of each point is quantized in voxel units. Accordingly, point cloud data is transformed into such data of voxels (also referred to as voxel data), so that an increase in the amount of information can be prevented (typically, the amount of information can be reduced).

<Octree>

Further, as for geometry data, construction of an octree using such voxel data has been suggested. An octree is a tree-structured version of voxel data. The value of each bit of the lowest nodes of this octree indicates the presence or absence of points in each voxel. For example, a value “1” indicates a voxel containing points, and a value “0” indicates a voxel containing no points. In the octree, one node corresponds to eight voxels. That is, each node of the octree is formed with 8-bit data, and the eight bits indicate the presence or absence of points in eight voxels.

Further, a higher node of the octree indicates the presence or absence of points in a region in which the eight voxels corresponding to the lower node belonging to the node are combined into one. That is, the higher node is generated by gathering the voxel information about the lower node. Note that, when the value of a node is “0”, or where all the eight corresponding voxels contain no points, the node is deleted.

In this manner, a tree structure (an octree) formed with nodes whose values are not “0” is constructed. That is, an octree can indicate the presence or absence of points in voxels at each resolution. By constructing and encoding an octree, the positional information is decoded from the highest resolution (the highest layer) to a desired hierarchical level (resolution). Thus, the point cloud data with that resolution can be restored. That is, decoding can be easily performed with a desired resolution, without decoding of information at unnecessary hierarchical levels (resolutions). In other words, voxel (resolution) scalability can be achieved.

Furthermore, as the nodes having the value “0” are eliminated as described above, the voxels in the regions without points can be lowered in resolution. Thus, an increase in the amount of information can be further prevented (typically, the amount of information can be reduced).

<Attribute Data>

As a method for encoding such attribute data, a method or the like using region adaptive hierarchical transform (RAHT) or transform called “lifting” has been conceived, for example. By adopting these techniques, it is possible to hierarchize attribute data like an octree of geometry data.

<Encoding of Point Cloud>

As of September 2019, standardization of point cloud data encoding and decoding is in progress by Moving Picture Experts Group (MPEG). Before that, as described in Non-Patent Document 1, techniques using voxels and octrees like those described above have been suggested, for example.

<Trisoup>

As one of such point cloud encoding methods, a method called “trisoup” in which points in a voxel are expressed by a plane in a triangular shape (also referred to as a triangular plane) has been considered as disclosed in Non-Patent Document 2, for example. By this method, a triangular plane is formed in a voxel, and only the vertex coordinates of the triangular plane are encoded on the assumption that all the points in that voxel exist. At the time of decoding, each point is then restored in the triangular plane derived from the vertex coordinates.

In this manner, a plurality of points in a voxel can be expressed simply by (the vertex coordinates of) a triangular plane. That is, by adopting a trisoup, it is possible to replace octree data of a predetermined intermediate resolution or lower with the data of this trisoup (the vertex coordinates of a triangular plane), for example. In other words, there is no need to perform transform into voxels of the highest resolution (leaf). Accordingly, the amount of information can be reduced, and encoding efficiency can be increased.

<Improvement of Point Restoration Methods>

When a trisoup is adopted, points are restored in a triangular plane during decoding. For example, a triangular plane is derived from decoded vertex coordinates, a sufficient number of points are arranged as appropriate in the triangular plane, and some points are deleted so as to leave the points with a necessary resolution. As decoding is performed in this manner in each voxel, a point cloud of a desired resolution can be restored.

Non-Patent Document 2 suggests this point restoration method as a method by which vectors (six directions) parallel to three axial directions (X, Y, and Z) perpendicular to one another are set in a voxel, and the points (referred to as intersections) at which the vectors intersect the triangular plane are set as the “points”.

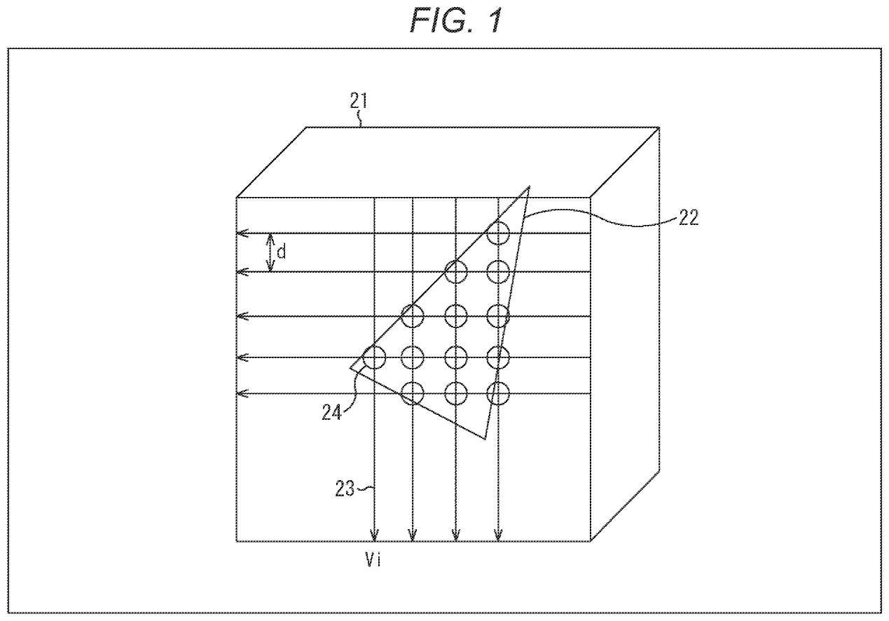

First, as shown in an example in FIG. 1, vectors Vi having the same direction and the same length as the sides of a bounding box including the data to be encoded is generated at intervals d. In FIG. 1, vectors Vi indicated by arrows 23 are set in a triangular plane 22 existing in a bounding box 21. The symbol “d” represents the quantization size at the time of transform of a bounding box into voxels. That is, vectors Vi having start origins at the position coordinates corresponding to a designated voxel resolution are set.

Next, intersection determination is performed between the set vectors Vi (the arrows 23) and the decoded triangular plane 22 (which is a triangular mesh). When the vectors Vi intersect the triangular plane 22, the coordinate values of the intersections 24 are calculated.

Note that, as the orientations of the vectors Vi, two positive and negative orientations can be set for each direction (a direction parallel to each side of the bounding box) of the three axial directions (X, Y, and Z) perpendicular to one another. That is, intersection determination may be performed for each of the vectors Vi of the six types of orientations. As intersection determination is performed with a larger number of orientations, intersections can be more reliably detected.

Note that the start points of the vectors Vi may be limited to the range of the three vertices of the triangular plane. By doing so, it is possible to reduce the number of vectors Vi to be processed, and thus, reduce the increase in load (for example, processing can be performed at higher speed).

Further, when the coordinate values of the intersections overlap between different vectors or in the triangular plane, intersections except for one may be deleted in auxiliary processing. By deleting the overlapping points in this manner, it is possible to reduce the increase in unnecessary processing, and reduce the increase in load (for example, processing can be performed at higher speed).

Further, when the coordinate values of the intersections are outside the bounding box, the positions of the intersections may be clipped (moved) into the bounding box by a clip process as auxiliary processing. Alternatively, the intersections may be deleted.

In the above manner, the points having the calculated coordinate values are output as a decoding result. In this manner, voxel data corresponding to the input resolution can be generated from the triangular plane by a single process. Thus, it is possible to reduce the increase in load when generating a point cloud from the triangular plane.

<Control on the Number of Points During Encoding>

However, in a conventional trisoup, the number of the points in the point cloud to be obtained by decoding cannot be controlled during encoding.

For example, when the upper limit of the number of points is determined by the profile or the level, there is no guarantee that the restrictions will be complied with at the decoding side. Therefore, the magnitude of the load of the decoding process cannot be guaranteed, and there is a possibility that the load of the decoding process is too large for the performance of the decoder and will lead to a delay in the decoding process or a failure of the decoding process, for example.

To counter this, when the points in a point cloud are expressed as a plane and are encoded, the number of the points in the point cloud to be obtained by decoding the encoded data is controlled.

For example, control information for controlling the number of the points to be derived from 3D data having a plane expressing the points in a point cloud that expresses a three-dimensional object as a set of points is supplied from the encoding side that encodes the 3D data to the decoding side that decodes the encoded data of the 3D data.

In this manner, when the encoded data of the 3D data is decoded, the points can be derived from the 3D data on the basis of the control information, and the point cloud can be restored. Thus, the encoding side can control the number of the points in the point cloud to be obtained by decoding.

This control information may be supplied from the encoding side to the decoding side in any appropriate manner. For example, this control information may be supplied as different data from the encoded data of the 3D data, from the encoding side to the decoding side. In that case, the control information and the 3D data should be associated with each other so that the control information can be used at the time of decoding the 3D data.

Alternatively, this control information and the encoded data of the 3D data may be included in one bitstream, and be supplied from the encoding side to the decoding side. That is, the encoding side may generate a bitstream that includes the encoded data of 3D data having a plane expressing the points in a point cloud that expresses a three-dimensional object as a set of points, and the control information for controlling the number of the points to be derived from the 3D data to be obtained by decoding the encoded data.

For example, an information processing apparatus may include a generation unit that generates a bitstream that includes encoded data of 3D data having a plane expressing the points in a point cloud that expresses a three-dimensional object as a set of points, and control information for controlling the number of the points to be derived from the 3D data to be obtained by decoding the encoded data.

In this manner, when the points in a point cloud are expressed as a plane and are encoded, the number of the points in the point cloud to be obtained by decoding the encoded data can be controlled.

Meanwhile, the decoding side may decode a bitstream, to generate 3D data having a plane expressing the points in a point cloud that expresses a three-dimensional object as a set of points, and control information for controlling the number of the points to be derived from the 3D data, and derive the points from the 3D data on the basis of the control information.

For example, an information processing apparatus may include: a decoding unit that decodes a bitstream, to generate 3D data having a plane expressing the points in a point cloud that expresses a three-dimensional object as a set of points, and control information for controlling the number of the points to be derived from the 3D data; and a derivation unit that derives the points from the 3D data on the basis of the control information.

By doing so, it is possible to derive points from 3D data in accordance with control at the encoding side. That is, the encoding side can control the number of the points in the point cloud to be obtained by decoding encoded data.

Note that a plane expressing points may be any kind of plane, and may be a flat plane or a curved plane. Further, when points are expressed by a plane, the shape of the plane may be any kind of shape. For example, the shape may be a polygonal shape. A polygonal plane can be expressed by the coordinates of the respective vertices (vertex coordinates), for example. Further, this polygon may be a triangle, a quadrangle, or a polygon having five or more vertices, for example. When points are expressed by a plane in a triangular shape (also referred to as a triangular plane), the points can be expressed by three vertex coordinates. Accordingly, the increase in the amount of information can be made smaller than that when points are expressed by a polygonal plane having four or more vertices.

Furthermore, a method for expressing points by a plane can be implemented in each appropriate region. For example, points may be expressed by a plane in each voxel having a predetermined resolution. That is, a plane may be formed in a voxel having a predetermined intermediate resolution, and all the points having the highest resolution located in the voxel may be expressed by the plane. In this manner, the high-resolution (lower layer) portions in which the amount of information remarkably increases can be expressed by a plane when a point cloud is hierarchized and encoded in accordance with resolution, for example. Thus, the increase in the amount of information can be reduced.

That is, a trisoup disclosed in Non-Patent Document 2 or the like may be adopted as 3D data that expresses the points in a point cloud by a plane. Furthermore, as disclosed in Non-Patent Document 2, the decoding side may derive points as the intersecting points between a triangular plane and vectors in three axial directions perpendicular to one another. By adopting such a method, points can be derived more easily.

In the description below, a case where a trisoup as disclosed in Non-Patent Document 2 or the like is adopted is explained. That is, the following is a description of an example case where the points in a point cloud are expressed by a triangular plane and are encoded, and, at the time of decoding, the points are derived as the intersections between the triangular plane and vectors in three axial directions perpendicular to one another.

The control information described above may be information for controlling anything in any manner, as long as the number of the points to be derived from 3D data to which a trisoup is applied (also referred to as trisoup data) can be controlled eventually. For example, sampling information for designating the interval between the vectors in the three axial directions perpendicular to one another may be included. As described above with reference to FIG. 1, the vectors Vi in the three axial directions perpendicular to one another are arranged at intervals d. The interval d may be designated.

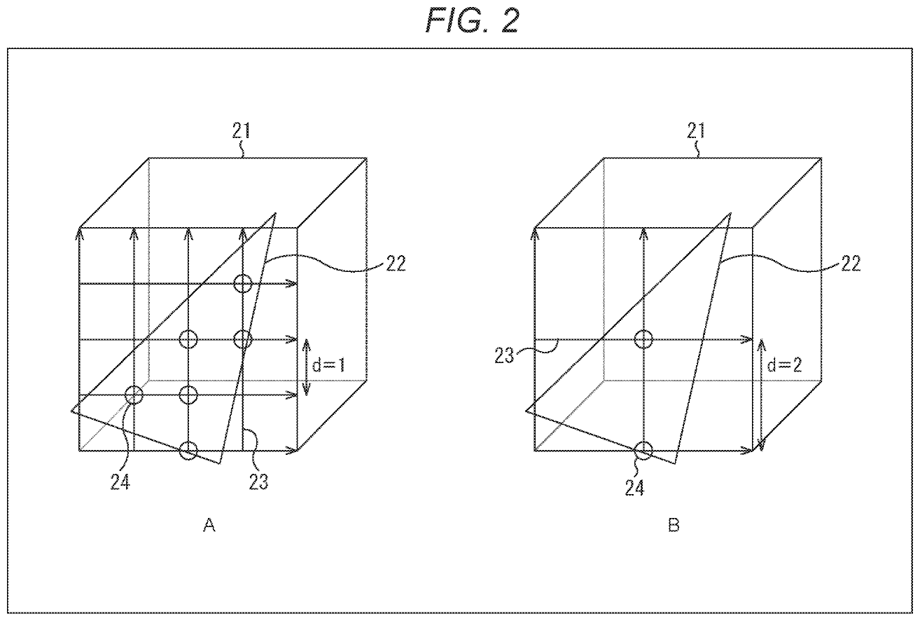

For example, as shown in A of FIG. 2, when the interval d=1, six intersections 24 between the vectors Vi (arrows 23) and the triangular plane 22 are obtained. If the interval d is doubled (d=2), for example, the number of the intersections 24 to be obtained decreases (two in this example case), as shown in an example in B of FIG. 2. That is, by controlling the interval d, it is possible to control the number of the points that can be easily restored.

<Limitation on the Number of Points by Level>

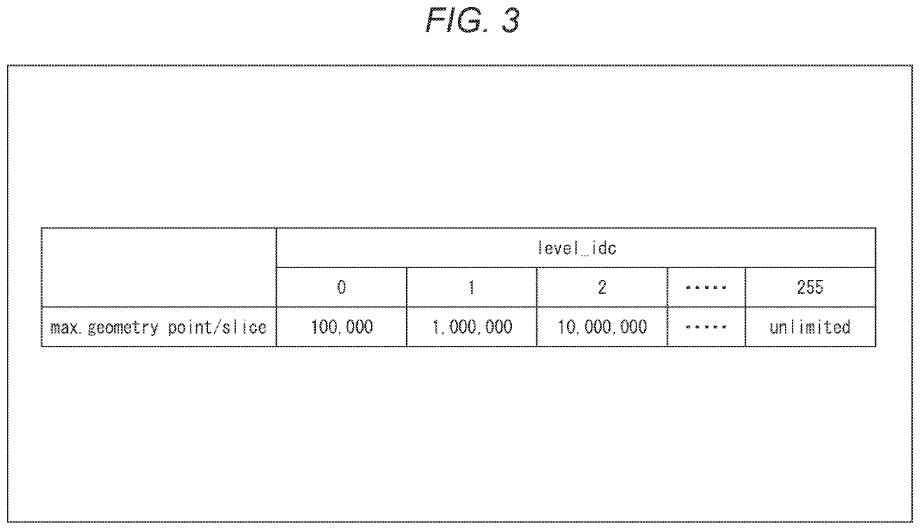

For example, the upper limit of the number of points may be set by the profile or the level. For example, as shown in FIG. 3, a maximum number of points per slice may be set for each level. In the example case in FIG. 3, the number of points per slice is limited to a maximum of 100,000 at level 0. At level 1, the number of points per slice is limited to a maximum of 1,000,000. At level 2, the number of points per slice is limited to a maximum of 10,000,000. Likewise, a maximum number of points is set for each level. At level 255, the number of points per slice is unlimited.

With the control information as described above, the number of the points to be restored at the decoding side can be controlled at the encoding side. That is, with the control information as described above, the number of the points to be restored at the decoding side can be limited at the encoding side. For example, in the example case shown in FIG. 2, it is possible to reduce the number of the points to be restored by widening the interval d between the vectors Vi.

Accordingly, when the upper limit of the number of points is determined by the profile or the level as in the example in FIG. 3, it is possible to comply with the restrictions depending on the profile or the level by adopting the control information as described above.

<Slices and Tiles>

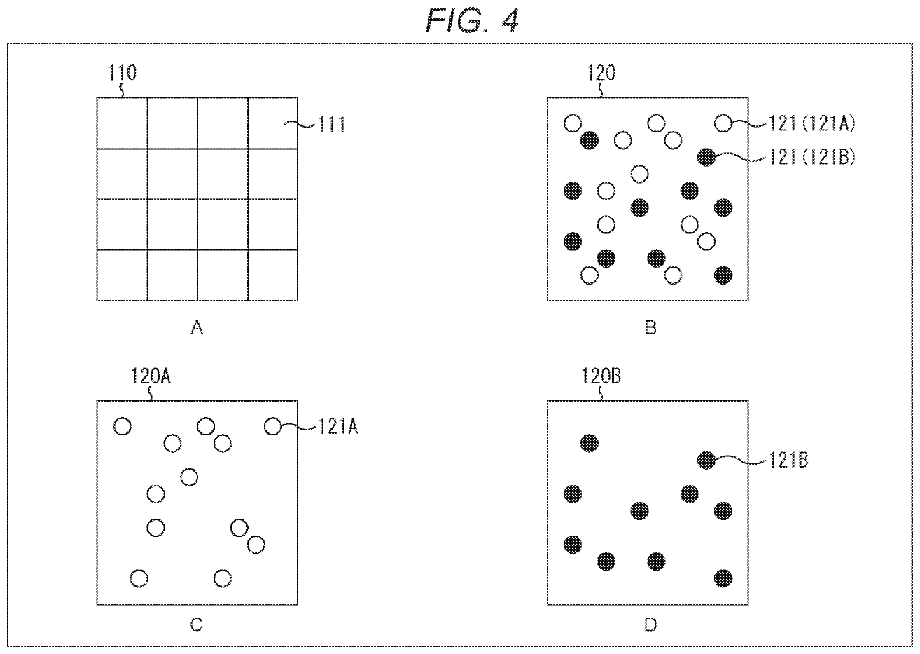

Here, slices and tiles in point cloud encoding and decoding are described with reference to FIG. 4. In FIG. 4, a three-dimensional region is shown as a two-dimensional region, for ease of explanation.

A tile is a data unit by which a three-dimensional region in which a point cloud exists is divided. For example, as shown in A of FIG. 4, a partial region 111 is called a tile when a region 110 is divided into a plurality of partial regions 111 in accordance with the position of the region 110.

On the other hand, a slice is a data unit by which a point cloud is divided into a plurality of pieces. For example, as shown in B of FIG. 4, a plurality of points 121 exists in a region 120. As shown in C of FIG. 4 and D of FIG. 4, each of the two groups of points 121A and points 121B into which the plurality of points 121 is divided is called a slice. That is, in the case of FIG. 4, the point cloud (B of FIG. 4) in the region 120 is divided into a slice 120A (C of FIG. 4) and a slice 120B (D of FIG. 4).

As described above, a slice is a data unit by which a point group is divided, regardless of regions.

Therefore, as in the example in FIG. 4, regions may overlap between a plurality of slices. Typically, a point cloud in one region is divided into a plurality of slices. For example, a point cloud in a tile can be divided into a plurality of slices.

The point clouds in the respective slices can be encoded and decoded independently of each other.

Accordingly, the point clouds in the respective slices can be processed in parallel with each other, for example. As described above, a slice is a data unit for facilitating parallel processing of point clouds in a predetermined region.

<Control for Each Slice>

The control information described above may be set for each desired data unit. For example, the control information may be set for each slice. For example, the control information (sampling information) may designate the interval d between the vectors Vi, slice by slice. Since encoding and decoding of the point cloud in each slice is independent as mentioned above, it is possible to facilitate the control thereon by controlling the number of the points in each slide. For example, when the value of the interval d is switched, the switching can be performed at a timing independent of encoding and decoding. Thus, there is no need to perform any complicated process such as considering the influence of a change in the interval d on other processes.

<Configuration of a Bitstream>

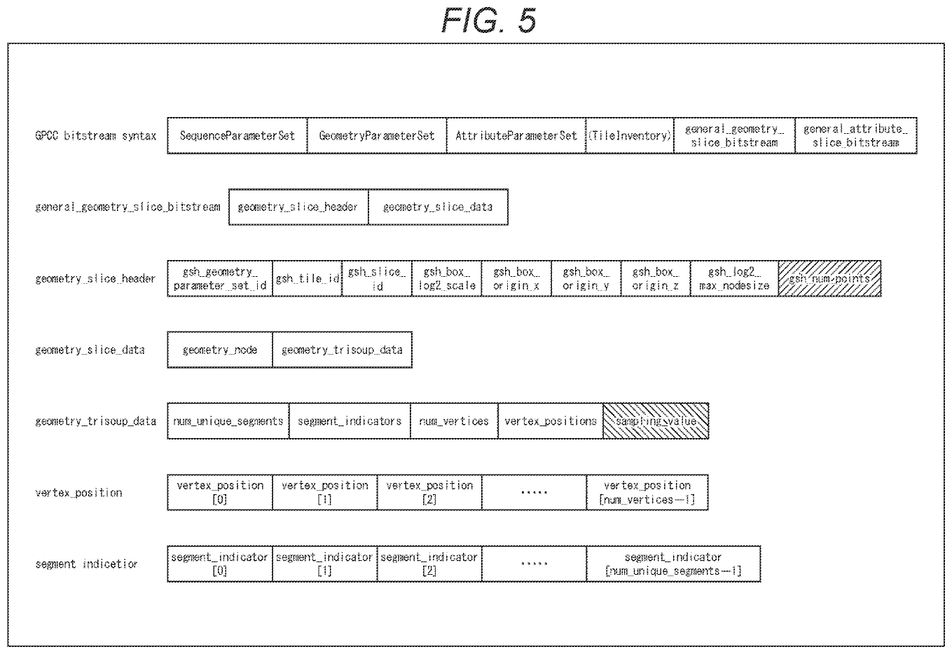

FIG. 5 shows a typical example configuration of a bitstream including the above control information. Note that the control information (sampling information) is designed for controlling the number of the points to be restored in each slice (or for designating the interval d between the vectors Vi in each slice). As shown in the top row in FIG. 5, the bitstream of this point cloud (GPCC bitstream syntax) may include a sequence parameter set (SequenceParameterSet), a geometry parameter set (GeometryParameterSet), an attribute parameter set (AttributeParameterSet), a tile inventory (TileInventory), a general geometry slice bitstream (general_geometry_slice_bitstream), and a general attribute slice bitstream (general_attribute_slice_bitstream).

The sequence parameter set may include a parameter related to this sequence. The geometry parameter set may include parameters related to the geometry data of this sequence. The attribute parameter set may include parameters related to the attribute data of the sequence. The tile inventory may include information related to tiles. The general geometry slice bitstream may include a bitstream of each slice of the geometry data. The general attribute slice bitstream may include a bitstream of each slice of the attribute data.

Further, as shown in the second row from the top in FIG. 5, the general geometry slice bitstream may include a geometry slice header (geometry_slice_header) and geometry slice data (geometry_slice_data). The geometry slice header may include metadata and the like related to each slice of the geometry data. The geometry slice data may include encoded data of each slice of the geometry data.

Further, as shown in the third row from the top in FIG. 5, the geometry slice header may include a geometry parameter set ID (gsh_goemetry_parameter_set_id), a tile ID (gsh_tile_id), a slice ID (gsh_slice_id), information related to size (gsh_box_log2_scale), information related to position (gsh_box_origin_x, gsh_box_origin_y, gsh_box_origin_z), information related to node size (gsh_log2_max_nodesize), and information related to the number of points (gsh_num_points).

The geometry parameter set ID may include identification information about the geometry parameter set corresponding to this geometry slice header. The tile ID may include identification information about the tile corresponding to each slice. The slice ID may include identification information about each slice. The information related to size may include information related to the size of the box (a three-dimensional region) of each slice. The information related to position may include information related to the position of the box of each slice, such as the coordinates of the reference position of the box of each slice, for example. For example, gsh_box_origin_x may include the X-coordinate of the reference position of the box of each slice. Also, gsh_box_origin_y may include the Y-coordinate of the reference position of the box of each slice. Also, gsh_box_origin_z may include the Z-coordinate of the reference position of the box of each slice. Note that the X-axis, the Y-axis, and the Z-axis are the three axes perpendicular to one another, the X-coordinate indicates the coordinate in the X-axis direction, the Y-coordinate indicates the coordinate in the Y-axis direction, and the Z-coordinate indicates a coordinate in the Z-axis direction. Furthermore, the information related to node size may include information indicating the maximum value of a node size of each slice.

The information related to the number of points may include information indicating the number of points included in each slice.

Further, as shown in the fourth row from the top in FIG. 5, the geometry slice data may include a geometry node (geometry_node) and geometry trisoup data (geometry_trisoup_data). The geometry node may include encoded data of octree data. The geometry trisoup data may include encoded data of trisoup data.

Further, as shown in the fifth row from the top in FIG. 5, the geometry trisoup data includes information related to the number of segments (num_unique_segments), indicators of the segments (segment_indicators), information related to the number of vertices (num_vertices), information related to vertex coordinates (vertex_positions), and sampling information (sampling_value).

The information related to the number of segments may include information indicating the number of the indicators of the segments included in this slice. The indicators of the segments may include the indicator of each segment, as shown in the seventh row from the top in FIG. 5. The information related to the number of vertices may include information indicating the number of the vertex coordinates included in this slice. The information related to vertex coordinates may include information indicating the coordinates of each vertex, as shown in the sixth row from the top in FIG. 5.

The sampling information is control information including information for designating the above-mentioned interval d between the vectors Vi. This interval d is set so that the number of the points to be restored from a triangular plane at the time of decoding is equal to or smaller than the number of the points designated in the “information related to the number of points” described above.

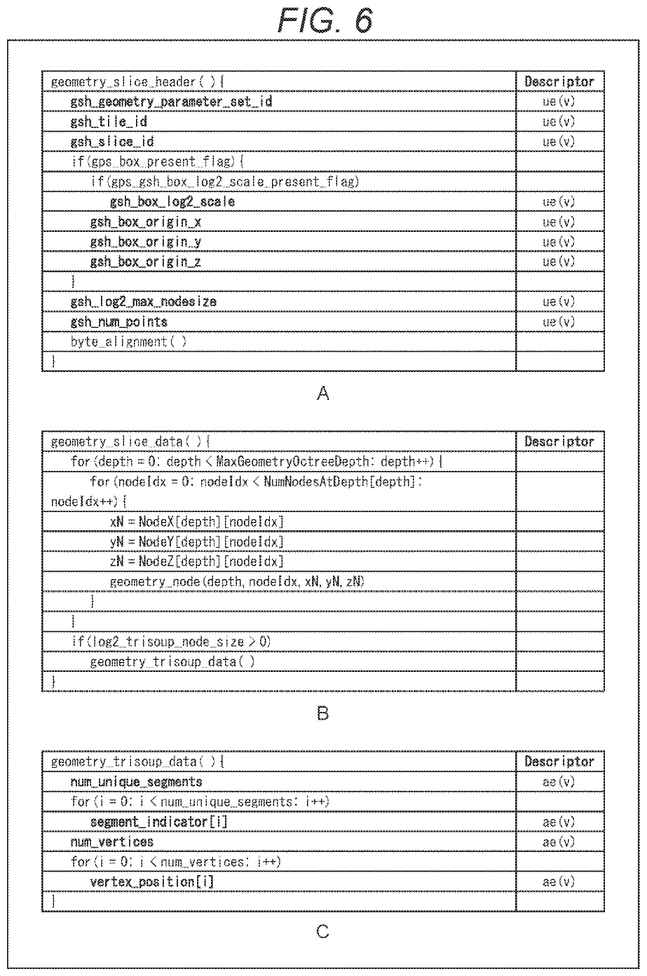

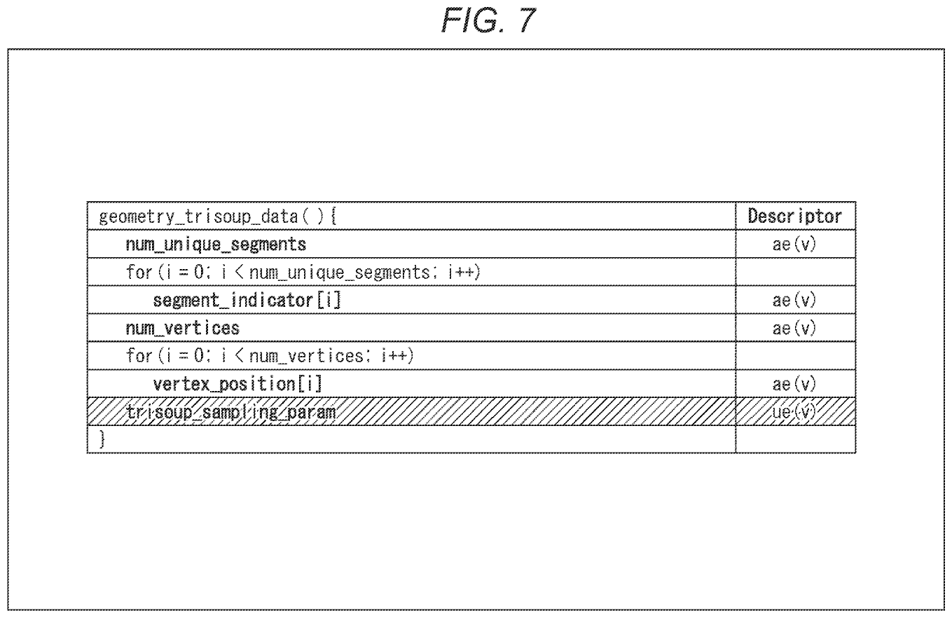

FIGS. 6 and 7 are charts showing a more specific example of the syntax of the general geometry slice bitstream (general_geometry_slice_bitstream).

A of FIG. 6 shows an example of the geometry slice header (geometry_slice_header) included in the general geometry slice bitstream. As shown in A of FIG. 6, in the geometry slice header, various syntax elements may be written, such as a geometry parameter set ID (gsh_goemetry_parameter_set_id), a tile ID (gsh_tile_id), a slice ID (gsh_slice_id), information related to size (gsh_box_log2_scale), information related to position (gsh_box_origin_x, gsh_box_origin_y, gsh_box_origin_z), information related to node size (gsh_log2_max_nodesize), and information related to the number of points (gsh_num_points), as shown in the third row from the top in FIG. 5.

B of FIG. 6 shows an example of the geometry slice data (geometry_slice_data) included in the general geometry slice bitstream. As shown in B of FIG. 6, in the geometry slice data, a geometry node (geometry_node (depth, nodeIdx, xN, yN, zN)) and geometry trisoup data (geometry_trisoup_data ( )) may be written, as shown in the fourth row from the top in FIG. 5.

C of FIG. 6 shows an example of conventional geometry trisoup data. As shown in C of FIG. 6, syntax elements such as num_unique_segments, segment_indicator[i], num_vertices, and vertex_position[i] may be written in the conventional geometry trisoup data.

The sampling information (sampling_value) shown in the fifth row from the top in FIG. 5 is written in the geometry trisoup data. FIG. 7 shows an example of the geometry trisoup data in that case. In the example in FIG. 7, this sampling information is written as a syntax element “trisoup_sampling_param”. That is, this trisoup_sampling_param is a syntax element for designating the interval d between the vectors Vi. In this case, the vectors Vi are arranged so that the interval in the X-axis direction, the interval in the Y-axis direction, and the interval in the Z-axis direction of the vectors Vi all have this value d.

As the control information for controlling the number of the points to be restored for each slice is stored into slice data (the geometry trisoup data, for example) in the above manner, the control information corresponding to the slice to be processed can be more easily identified at the decoding side that performs decoding using this information. Thus, the decoding process can be further facilitated, and the increase in the decoding load can be reduced.

<d-Value>

Note that, when such control information for controlling the number of the points to be restored designates the interval d between the vectors Vi like the sampling information, this interval d may be designated with an integer value, or may be designated with a decimal value. The decoding process can be made easier when the control information designates the interval d with an integer value. However, the number of points can be more finely controlled when the control information designates the interval d with a decimal value.

<Control Independent in Each Direction>

Also, the interval d between the vectors Vi may be controlled independently in each of the vector directions (the three axial directions perpendicular to one another (the x, y, and z directions)). In other words, the interval between the start origins of the respective vectors Vi 603 in the three axial directions (the x-, y-, and z-directions) perpendicular to one another may be independent in each direction.

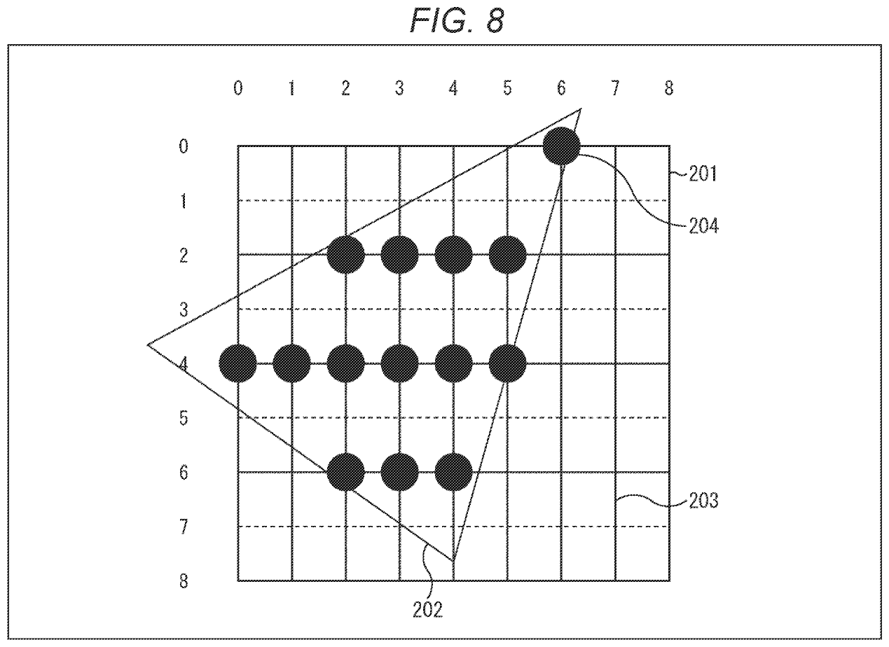

FIG. 8 is a diagram for explaining a state of a voxel in a two-dimensional plane. In FIG. 8, a triangular plane 202 is formed in a voxel 201. For example, where vectors Vi in a direction perpendicular to the paper surface are arranged at the intersecting points between solid lines 203 in the vertical direction in the drawing and the horizontal direction in the drawing of the voxel 201, the intersections 204 between the vectors Vi and the triangular plane 202 are as shown in FIG. 8. That is, the interval between the intersections 204 in the vertical direction in the drawing is twice as wide as the interval in the horizontal direction in the drawing. That is, as for the interval d between the vectors Vi, the interval in the vertical direction in the drawing is twice as wide as the interval in the horizontal direction in the drawing. As the interval d between the vectors Vi is set independently for each axial direction in this manner, the number of points can be controlled more finely than when control is performed using a common value for all the axial directions.

Since a voxel is a three-dimensional region in practice, the interval d between the vectors Vi may be set independently for each of the three directions of the X direction, the Y direction, and the Z direction. That is, in the sampling information, the interval dx in the X-axis direction, the interval d_{Y} in the Y-axis direction, and the interval d_{Z} in the Z-axis direction may be set independently of one another.

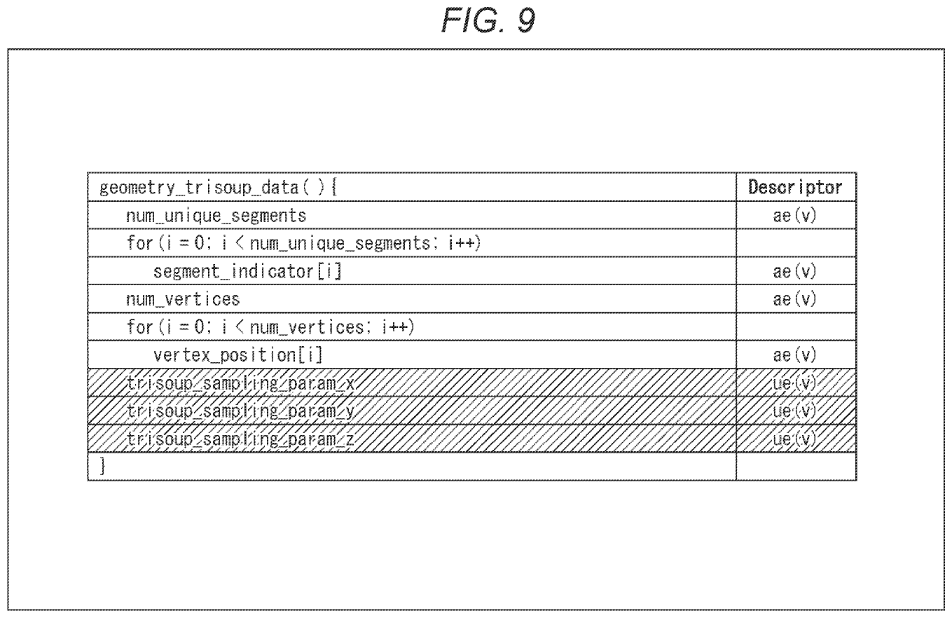

FIG. 9 shows an example of the syntax of the geometry trisoup data in that case. In the example in FIG. 9, syntax elements “trisoup_sampling_param_x”, “trisoup_sampling_param_y”, and “trisoup_sampling_param_z” are written as the sampling information. This “trisoup_sampling_param_x” is a syntax element for designating the interval between the vectors Vi in the X-axis direction. The syntax element “trisoup_sampling_param_y” is a syntax element for designating the interval between the vectors Vi in the Y-axis direction. The syntax element “trisoup_sampling_param_z” is a syntax element for designating the interval between the vectors Vi in the Z-axis direction. That is, in this case, the interval between the vectors Vi in the respective axis directions of the X-axis direction, the Y-axis direction, and the Z-axis direction can be set independently of one another in the sampling information.

<Control Other than Interval Control>

<Preferential Deletion of Points Inside a Triangular Plane>

Note that a method for controlling the number of points to be restored may be any appropriate method, and may not be a method for controlling the interval between the vectors Vi as in the above-mentioned example of the sampling information. For example, when the number of points is to be reduced, the intersections in a portion inside a triangular plane (a portion far from each side of the triangular plane) may be preferentially deleted from the intersections between the triangular plane and the vectors Vi. For example, the control information may be designed for designating an operation mode in which the intersections in the portion inside the triangular plane are preferentially deleted. In this case, the decoding side selects an operation mode on the basis of the control information, and performs processing so as to preferentially delete the intersections in the portion inside the triangular plane.

In this manner, the resolution around each side of the triangular plane can be made higher than that in the other portions. That is, in the point cloud data, the configuration of the respective sides of the triangular plane can be more accurately expressed. Thus, the three-dimensional structure expressed by this triangular plane can be more accurately expressed by the point cloud data.

<Addition of Points>

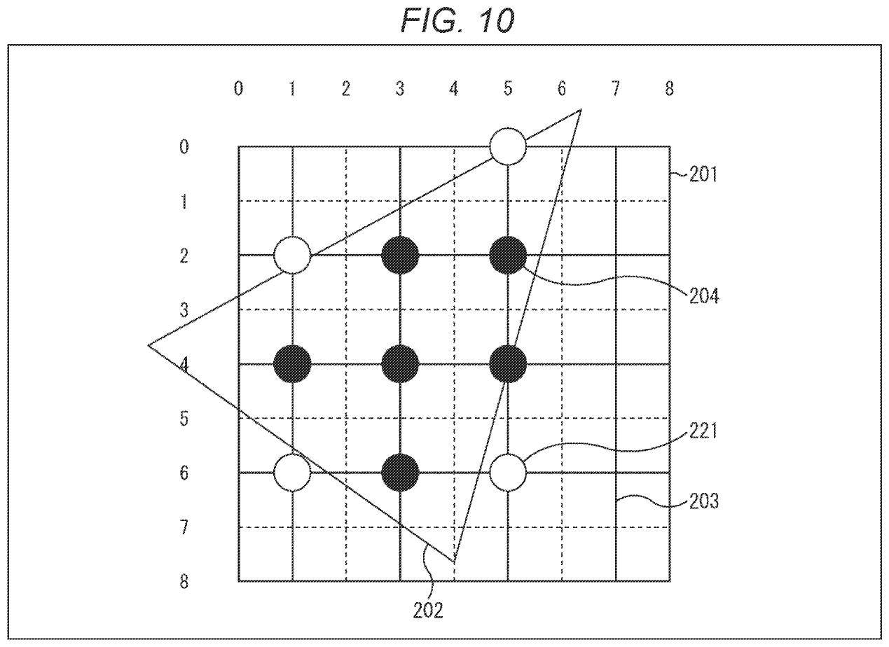

Furthermore, points that are not located at any intersection between the vectors Vi and the triangular plane may be generated and be included in the point cloud data. For example, in FIG. 10, the vectors Vi in a direction perpendicular to the paper surface are arranged at the intersections between the solid lines 203 in the vertical direction and the horizontal direction in the drawing of the voxel 201. In this case, as shown in FIG. 10, points 221 (white circles) may be generated at positions of vectors Vi not intersecting the triangular plane 202, and be included in the point cloud data, the positions being close to the respective sides of the triangular plane 202. Note that the method for determining the positions at which the points are generated (the method for determining the points close to the respective sides) may be any appropriate method.

For example, the control information may be designed for designating an operation mode in which the points are restored at the positions where the vectors Vi are close to the respective sides of the triangular plane as above. In that case, the decoding side selects an operation mode on the basis of the control information, and performs processing so as to restore the points at the positions where the vectors Vi are close to the respective sides of the triangular plane.

In this manner, the resolution around each side of the triangular plane can be made higher than that in the other portions. That is, in the point cloud data, the configuration of the respective sides of the triangular plane can be more accurately expressed. Thus, the three-dimensional structure expressed by this triangular plane can be more accurately expressed by the point cloud data.

<Control on the Positions of Start Origins>

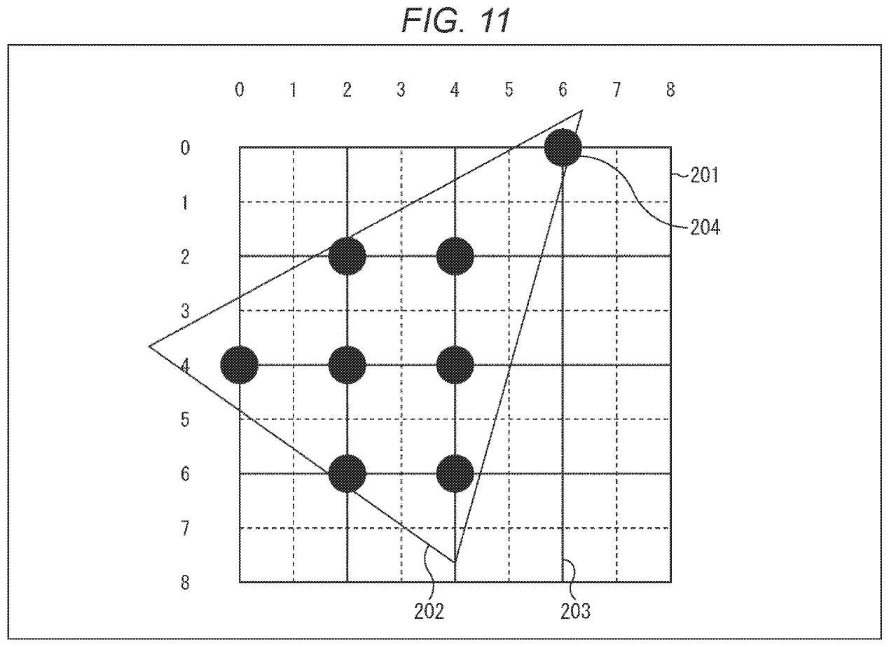

Furthermore, the positions of the start origins of the vectors Vi may be controlled. For example, in the case shown in FIG. 11, a vector Vi in the direction perpendicular to the paper surface is placed at an intersection between the straight lines 203, or is placed at a position that is a position denoted by 0, 2, 4, 6, or 8 in the horizontal direction in the drawing, and is a position denoted by 0, 2, 4, 6, or 8 in the vertical direction in the drawing. As a result, eight intersections 204 are formed between the vectors Vi and the triangular plane 202, as shown in FIG. 11.

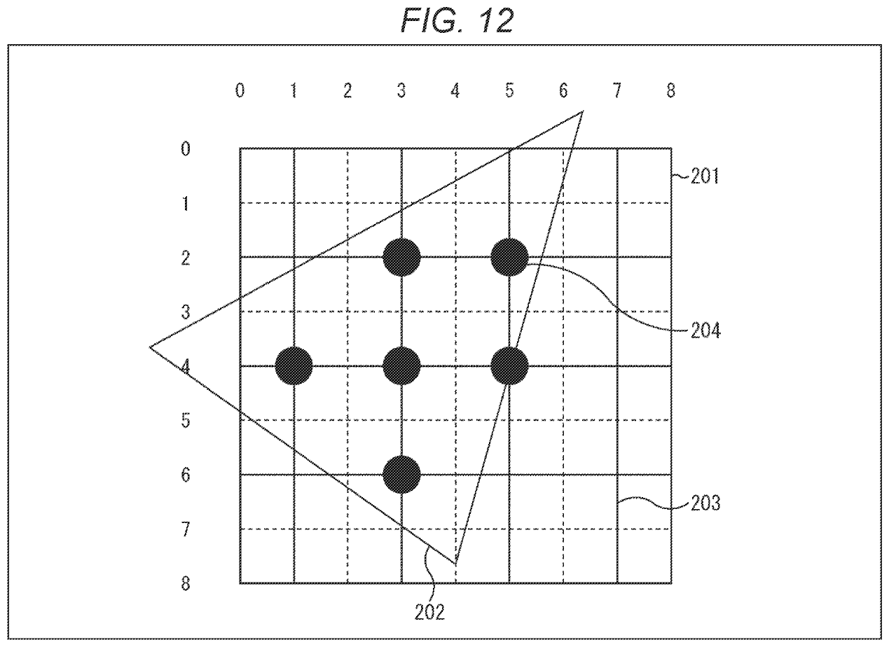

In the case shown in FIG. 12, on the other hand, a vector Vi in the direction perpendicular to the paper surface is placed at an intersection between the straight lines 203, or is placed at a position that is a position denoted by 1, 3, 5, or 7 in the horizontal direction in the drawing, and is a position denoted by 0, 2, 4, 6, or 8 in the vertical direction in the drawing. As a result, six intersections 204 are formed between the vectors Vi and the triangular plane 202, as shown in FIG. 12.

By changing the positions of the vectors Vi in this manner, it is possible to change the number of the intersections with the triangular plane. That is, by controlling the positions of the vectors Vi, it is possible to control the number of the points to be restored.

For example, the control information may be designed for designating the positions of the vectors Vi (the positions of the start origins of the vectors Vi) in this manner. For example, the control information may include information for designating the positions of the vectors Vi. In that case, at the decoding side, the vectors Vi are arranged at the positions designated on the basis of the control information, and the intersections between the vectors Vi and the triangular plane are derived.

By doing so, it is possible to control the number of points without a change in the resolution of the point cloud. Thus, the number of points can be more finely controlled.

<Point Generation at Some of the Intersections>

Note that points may be generated at some of the intersections between the vectors Vi and the triangular plane. In other words, a point is not necessarily generated at an intersection. That is, the number of the intersections at which points are to be generated may be reduced so that the resolution of the point cloud is lowered (or resolution scalability is achieved).

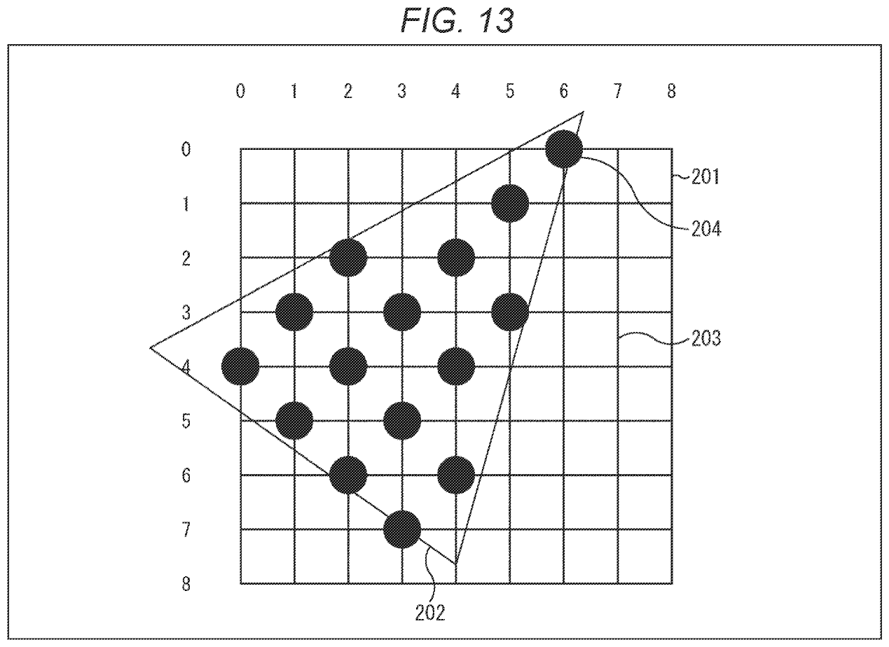

The method for selecting the intersections at which points are to be generated (or points are not to be generated) may be any appropriate method. For example, as shown in FIG. 13, points may be generated in a staggered manner (at every other intersection in each of the three axial directions).

For example, the control information may be designed for designating at which intersections points are to be generated. For example, the control information may include information for designating the pattern (a staggered pattern or the like, for example) of intersections at which points are to be generated. In that case, the decoding side can restore points at the intersections at the positions corresponding to the designated pattern among the derived intersections, on the basis of the control information.

In this manner, the number of the points to be restored can be controlled, regardless of the interval between the vectors Vi (or the number of the vectors Vi). Thus, the number of points can be controlled by a wider variety of methods.

<Combinations>

As for the respective methods described in this embodiment, any appropriate combination of a plurality of methods can be adopted.

<Method Selection>

Furthermore, a desired method (or a desired combination of methods) may be selected from among some or all of the respective methods described in this specification, and be adopted. In that case, the selection method is may be any appropriate method. For example, all adoption patterns may be evaluated, and the best one may be selected. In this manner, point cloud data can be generated by the method most suitable for a three-dimensional structure or the like.

<Storage Position of the Control Information>

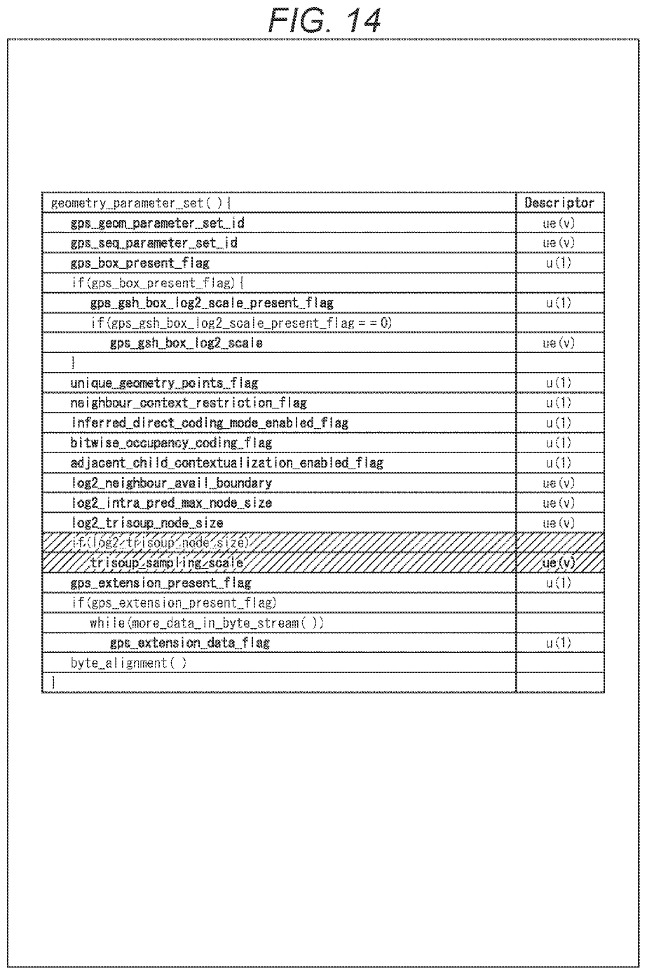

Although the control information is included in slice data as described above with reference to FIGS. 5 and 7, the storage position of the control information in a bitstream may be any appropriate position, and is not limited to the above example. For example, as shown in FIG. 14, the control information may be stored in the geometry parameter set (geometry_parameter_set).

In the example case shown in FIG. 14, the control information (trisoup_sampling_scale) set for each slice is stored in this geometry parameter set. That is, the control information for all the slices is stored in this geometry parameter set.

Accordingly, the decoding side can easily obtain the control information for all the slices by referring to this geometry parameter set.

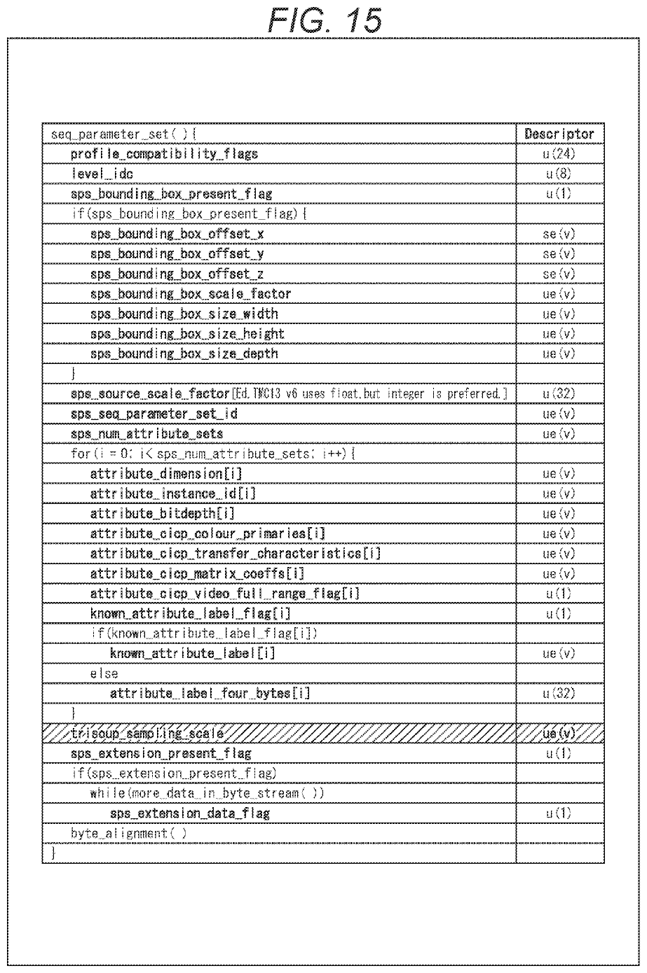

Alternatively, as shown in FIG. 15, the control information may be stored in the sequence parameter set (seq_parameter_set), for example.

In the example case shown in FIG. 15, the control information (trisoup_sampling_scale) set for each slice is stored in this sequence parameter set. That is, the control information for all the slices is stored in this sequence parameter set.

Note that this control information may be stored at a plurality of positions in a bitstream. For example, this control information may be stored in the geometry trisoup data, the geometry parameter set, and the sequence parameter set (FIGS. 7, 14, and 15). In that case, the control information stored in a lower data unit may be preferentially adopted. For example, when there is the control information corresponding to the slice to be processed, the control information may be preferentially adopted. When there is no control information corresponding to the slice to be processed, the control information stored in the geometry parameter set may be adopted.

### 2. FIRST EMBODIMENT

<Encoding Device>

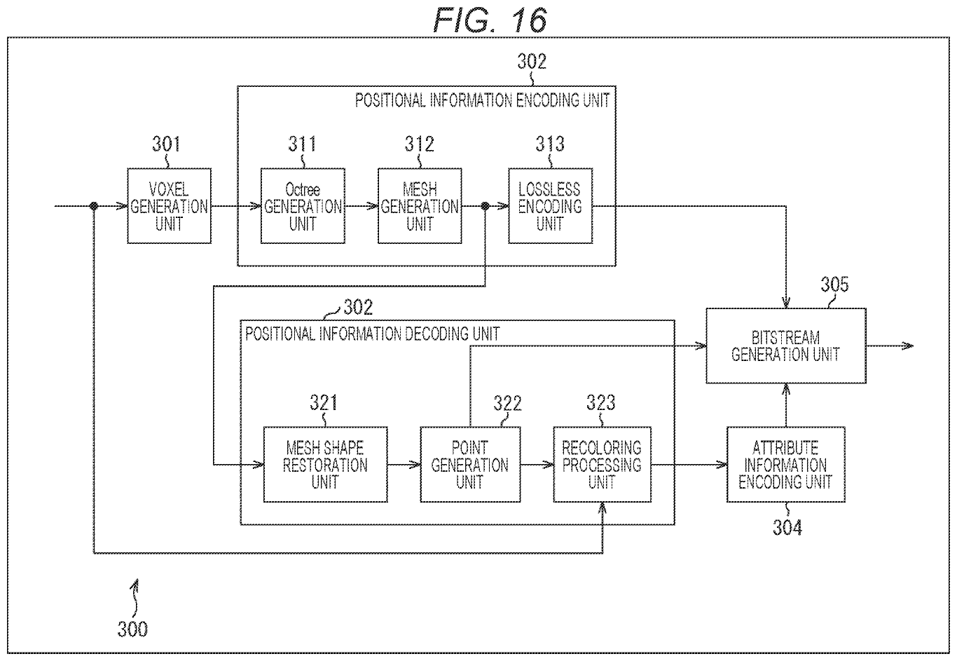

FIG. 16 is a block diagram showing an example configuration of an encoding device as an embodiment of an image processing apparatus to which the present technology is applied. An encoding device 300 shown in FIG. 16 is a device that encodes 3D data such as a point cloud. In this encoding, the encoding device 300 encodes a point cloud, using a technique such as voxel, octree, or trisoup. Also, at the time of the encoding, the encoding device 300 controls the number of the points in the point cloud to be obtained by decoding encoded data as described above in <1. Trisoup Point Number Control>. For example, the encoding device 300 generates control information for controlling the number of the points to be derived from a triangular plane of a trisoup, and supplies the control information to the decoding side that decodes encoded data of the trisoup.

In doing so, the encoding device 300 can adopt the various methods described above in <1. Trisoup Point Number Control>.

Note that FIG. 16 shows the principal components and aspects such as processing units and a data flow, but FIG. 16 does not necessarily show all the components and aspects. That is, in the encoding device 300, there may be a processing unit that is not shown as a block in FIG. 16, or there may be a process or data flow that is not shown as an arrow or the like in FIG. 16. This also applies to the other drawings for explaining the processing units and the like in the encoding device 300.

As shown in FIG. 16, the encoding device 300 includes a voxel generation unit 301, a positional information encoding unit 302, a positional information decoding unit 303, an attribute information encoding unit 304, and a bitstream generation unit 305.

The voxel generation unit 301 performs a process related to conversion of a point cloud into voxels. For example, the voxel generation unit 301 can acquire point cloud data that is input to the encoding device 300. On the basis of the geometry data of the acquired point cloud data, the voxel generation unit 301 can also set a bounding box for the region including the point cloud. Further, the voxel generation unit 301 can divide the bounding box, and set voxels. As the voxels are set, the geometry data of the point cloud data is quantized. The voxel generation unit 301 can supply the voxel data generated in this manner to the positional information encoding unit 302.

The positional information encoding unit 302 performs a process related to encoding of geometry data (positional information). For example, the positional information encoding unit 302 can acquire the voxel data supplied from the voxel generation unit 301. The positional information encoding unit 302 can also encode the acquired voxel data, to generate encoded data of the geometry data. This encoding will be described later in detail. The positional information encoding unit 302 can supply the generated encoded data of the geometry data to the bitstream. The positional information encoding unit 302 can also supply intermediate data (the geometry data before lossless encoding) to the positional information decoding unit 303.

The positional information decoding unit 303 performs a process related to decoding of geometry data. For example, the positional information decoding unit 303 can supply the intermediate data (the geometry data before lossless encoding) supplied from the positional information encoding unit 302. The positional information decoding unit 303 can also acquire the point cloud data that is input to the encoding device 300. Further, the positional information decoding unit 303 can decode the acquired intermediate data, to restore the points. This decoding will be described later in detail. The positional information decoding unit 303 can also perform a recoloring process using the geometry data from which the points have been restored and the attribute data of the acquired point cloud data, and thus, update the attribute data so as to match the geometry data. Further, the positional information decoding unit 303 can supply the geometry data and the attribute data to the attribute information encoding unit 304. The positional information decoding unit 303 can also generate control information for controlling the number of the points to be restored at the time of decoding, and supply the control information to the bitstream generation unit 305.

The attribute information encoding unit 304 performs a process related to encoding of attribute information. For example, the attribute information encoding unit 304 can acquire the geometry data and the attribute data supplied from the positional information decoding unit 303. The attribute information encoding unit 304 can also encode the attribute data (attribute information) using the geometry data, to generate encoded data of the attribute data. The method for encoding this attribute data is any appropriate method. Further, the attribute information encoding unit 304 can supply the generated encoded data of the attribute data to the bitstream generation unit 305.

The bitstream generation unit 305 performs a process related to generation of a bitstream. For example, the bitstream generation unit 305 can acquire the encoded data of the geometry data supplied from the positional information encoding unit 302. The bitstream generation unit 305 can also acquire the encoded data of the attribute data supplied from the attribute information encoding unit 304. Further, the bitstream generation unit 305 can acquire the control information supplied from the positional information decoding unit 303. The bitstream generation unit 305 can generate a bitstream including the encoded data of the geometry data, the encoded data of the attribute data, and the control information. The bitstream generation unit 305 can output the generated bitstream to the outside of the encoding device 300.

For example, the bitstream generation unit 305 can transmit the bitstream to another device via a predetermined communication medium. The bitstream generation unit 305 can also store the bitstream into a predetermined storage medium. The bitstream output from the encoding device 300 in this manner is supplied, via a communication medium or a storage medium, to a device at the decoding side that decodes the bitstream, for example.

<Positional Information Encoding Unit>

As shown in FIG. 16, the positional information encoding unit 302 includes an octree generation unit 311, a mesh generation unit 312, and a lossless encoding unit 313, for example.

The octree generation unit 311 performs a process related to octree generation. For example, the octree generation unit 311 can acquire the voxel data supplied from the voxel generation unit 301. The octree generation unit 311 can also construct an octree using the voxel data, and generate octree data. The octree generation unit 311 can supply the generated octree data to the mesh generation unit 312.

The mesh generation unit 312 performs a process related to generation of trisoup data representing the points of the point cloud using a triangular plane. For example, the mesh generation unit 312 can acquire the octree data supplied from the octree generation unit 311. The mesh generation unit 312 can also generate trisoup data that represents nodes (points) with a predetermined resolution or lower in the octree data, using a triangular plane. Further, the mesh generation unit 312 can supply geometry data including the generated trisoup data and the octree data to the lossless encoding unit 313. The mesh generation unit 312 can also supply the geometry data to the positional information decoding unit 303.

The lossless encoding unit 313 performs a process related to encoding of geometry data. For example, the lossless encoding unit 313 can acquire the geometry data supplied from the mesh generation unit 312. The lossless encoding unit 313 can also perform lossless encoding on the acquired geometry data, to generate encoded data of the geometry data. Further, the lossless encoding unit 313 can supply the generated encoded data of the geometry data to the bitstream generation unit 305.

<Positional Information Decoding Unit>

As shown in FIG. 16, the positional information decoding unit 303 includes a mesh shape restoration unit 321, a point generation unit 322, and a recoloring processing unit 323, for example.

The mesh shape restoration unit 321 performs a process related to restoration of a triangular plane from trisoup data. For example, the mesh shape restoration unit 321 can acquire the geometry data supplied from the positional information encoding unit 302 (the mesh generation unit 312). This geometry data includes the octree data and the trisoup data. The mesh shape restoration unit 321 can also restore each triangular plane, on the basis of the trisoup data of the geometry data. The trisoup data includes the vertex coordinates of the triangular plane, and the mesh shape restoration unit 321 can restore the triangular plane using the vertex coordinates. Further, the mesh shape restoration unit 321 can supply geometry data having the restored triangular plane to the point generation unit 322.

The point generation unit 322 performs a process related to generation of points. For example, the point generation unit 322 can acquire the geometry data having the triangular plane supplied from the mesh shape restoration unit 321. The point generation unit 322 can also generate (restore) points using the triangular plane of the geometry data, and generate (restore) point cloud data. In doing so, the point generation unit 322 can generate points by appropriately adopting the various methods described in <1. Trisoup Point Number Control>. For example, the point generation unit 322 can generate points so that the points do not exceed a predetermined limit value (to comply with restrictions regarding profiles and levels, for example). Further, the point generation unit 322 can supply the geometry data of the point cloud data including the restored points to the recoloring processing unit 323.

The point generation unit 322 can also generate control information for controlling the number of the points to be restored in the decoding. In doing so, the point generation unit 322 can generate the control information by appropriately adopting the various methods described in <:1. Trisoup Point Number Control>.

For example, the point generation unit 322 can generate the control information for controlling the number of the points so that the number of the points to be restored at the time of decoding does not exceed a predetermined limit value. For example, the point generation unit 322 can generate the control information so that the number of the points to be restored at the time of decoding complies with restrictions regarding profiles and levels (that is, the number of the points is limited to a number equal to or smaller than the upper limit value depending on the profile or the level). Also, the point generation unit 322 can generate the control information so as to limit the number of the points to be restored at the time of decoding to a number that is equal to or smaller than the number of the points in the point cloud data that is input to the encoding device 300 (that is, the number of the points in the point cloud before the encoding), for example.

Further, the point generation unit 322 can supply the generated control information to the bitstream generation unit 305.

The recoloring processing unit 323 performs a process related to a recoloring process. For example, the recoloring processing unit 323 can acquire the geometry data supplied from the point generation unit 322. The recoloring processing unit 323 can also acquire the point cloud data that is input to the encoding device 300. The recoloring processing unit 323 can perform a recoloring process that is a process of adapting the attribute data of the point cloud data acquired from the outside of the encoding device 300 to the geometry data acquired from the point generation unit 322. The method in this recoloring process may be any appropriate method. Further, the recoloring processing unit 323 can supply the result of the recoloring process, which is the geometry data and the attribute data corresponding to the geometry data, to the attribute information encoding unit 304.

Note that each of these processing units (from the voxel generation unit 301 to the bitstream generation unit 305) of the encoding device 300 may have any appropriate configuration. For example, each processing unit may be formed with a logic circuit that performs the processes described above. Alternatively, each processing unit may include a central processing unit (CPU), a read only memory (ROM), a random access memory (RAM), and the like, for example, and execute a program using these components, to perform the processes described above. Each processing unit may of course have both configurations, and perform some of the processes described above with a logic circuit, and the other by executing a program. The configurations of the respective processing units may be independent of one another. For example, one processing unit may perform some of the processes described above with a logic circuit while the other processing units perform the processes described above by executing a program. Further, some other processing unit may perform the processes described above both with a logic circuit and by executing a program.

As described above, the bitstream generation unit 305 generates a bitstream including the control information generated by the point generation unit 322 appropriately adopting the various methods described in <1. Trisoup Point Number Control>. Accordingly, the encoding device 300 can control the number of the points in the point cloud to be obtained by decoding encoded data. That is, when the points in a point cloud are expressed as a plane and are encoded, the number of the points in the point cloud to be obtained by decoding the encoded data can be controlled.

<Point Generation Unit>

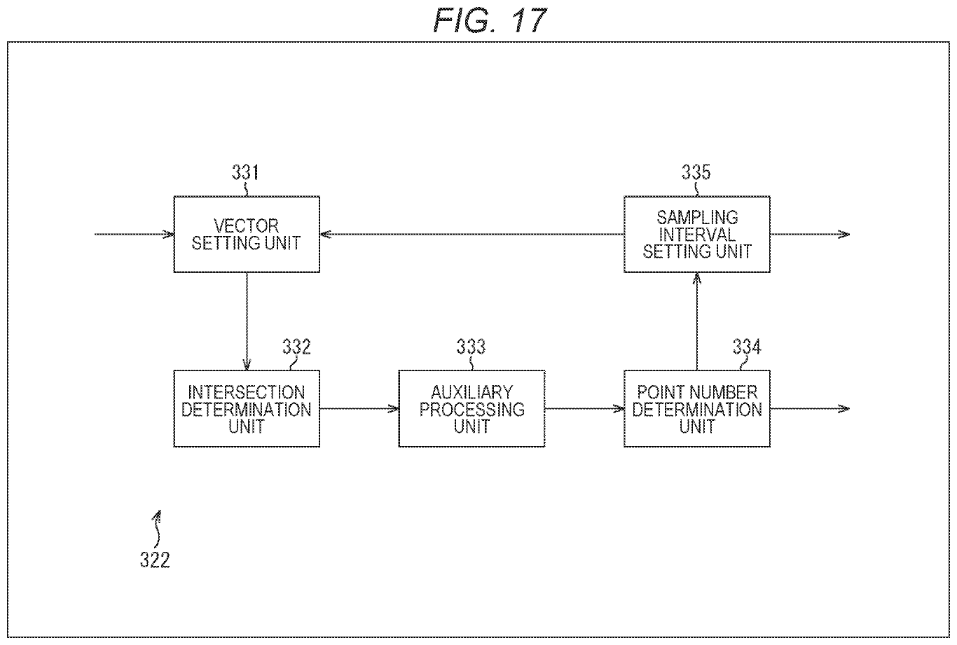

FIG. 17 is a block diagram showing a typical example configuration of the point generation unit 322 shown in FIG. 16. As shown in FIG. 17, the point generation unit 3322 includes a vector setting unit 331, an intersection determination unit 332, an auxiliary processing unit 333, a point number determination unit 334, and a sampling interval setting unit 335.

The vector setting unit 331 performs a process related to setting of vectors Vi for restoring points from a triangular plane. For example, the vector setting unit 331 can acquire the geometry data having a triangular plane supplied from the mesh shape restoration unit 321. The vector setting unit 331 can also acquire sampling information supplied from the sampling interval setting unit 335. This sampling information is information for controlling the interval d between vectors Vi as described above in <1. Trisoup Point Number Control>. Further, for the geometry data having a triangular plane, the vector setting unit 331 can set the vectors Vi described above in <1. Trisoup Point Number Control> at intervals based on the sampling information. The vector setting unit 331 can also supply the geometry data that has a triangular plane and has the vectors Vi set therein, to the intersection determination unit 332.

The intersection determination unit 332 performs a process related to determination of the intersections between the vectors Vi and a triangular plane. For example, the intersection determination unit 332 can acquire the geometry data that has a triangular plane, has the vectors Vi set therein, and is supplied from the vector setting unit 331. The intersection determination unit 332 can also determine the intersections between the triangular plane of the geometry data and the vectors Vi, and derive the coordinates of the intersections between the triangular plane and the vectors Vi (the intersections are also referred to as the intersection coordinates). Further, the intersection determination unit 332 can supply the derived intersection coordinates to the auxiliary processing unit 333.

The auxiliary processing unit 333 performs auxiliary processing on the intersections. For example, the auxiliary processing unit 333 can acquire the intersection coordinates supplied from the intersection determination unit 332. The auxiliary processing unit 333 can also perform predetermined auxiliary processing on the acquired intersection coordinates.

For example, when the coordinate values of the intersections overlap between different vectors or in the triangular plane, the auxiliary processing unit 333 may delete intersections except for one. By deleting the overlapping points in this manner, it is possible to reduce the increase in unnecessary processing, and reduce the increase in load (for example, processing can be performed at higher speed). Further, when the coordinate values of the intersections are outside the bounding box, the auxiliary processing unit 333 may clip (move) the positions of the intersections into the bounding box by a clip process. Alternatively, the intersections may be deleted.

The auxiliary processing unit 333 can supply the intersection coordinates subjected to the auxiliary processing, to the point number determination unit 334.

The point number determination unit 334 determines the number of the intersections (points). For example, the point number determination unit 334 can acquire the intersection coordinates from the auxiliary processing unit 333. The point number determination unit 334 can also determine whether or not the number of the intersection coordinates (which is the number of the restored points) satisfies a predetermined condition. For example, the number of the intersection coordinates can be compared with the upper limit value defined by the profile or the level. When it is determined that the number of the points does not satisfy the condition (or exceeds the upper limit value defined by the profile or the level, for example), the point number determination unit 334 can notify the sampling interval setting unit 335 to that effect. When it is determined that the number of the points satisfies the condition, on the other hand, the point number determination unit 334 can notify the sampling interval setting unit 335 to that effect, and further, supply the intersection coordinates as geometry data to the recoloring processing unit 323.

The sampling interval setting unit 335 performs a process related to setting of sampling information. For example, the sampling interval setting unit 335 can generate sampling information (or set the interval d between the vectors Vi), and supply the generated sampling information to the vector setting unit 331. In doing so, the sampling interval setting unit 335 can generate the sampling information by appropriately adopting the various methods described in <1. Trisoup Point Number Control>.

The sampling interval setting unit 335 can also acquire, from the point number determination unit 334, a notification as to whether or not the number of the restored points satisfies a predetermined condition.

Further, when the number of the restored points does not satisfy the predetermined condition on the basis of the notification, the sampling interval setting unit 335 can update the sampling information (or update the set value of the interval d between the vectors Vi), and supply the updated sampling information to the vector setting unit 331. In doing so, the sampling interval setting unit 335 can update the sampling information by appropriately adopting the various methods described in <1. Trisoup Point Number Control>.

When the number of the restored points satisfies the predetermined condition on the basis of the notification from the point number determination unit 334, on the other hand, the sampling interval setting unit 335 supply the currently set sampling information as control information to the bitstream generation unit 305.

Note that, although the sampling information has been described as an example of the control information herein, this control information may be information for controlling an item other than the interval d between the vectors Vi as described above in <1. Trisoup Point Number Control>.

As the sampling interval setting unit 335 generates the control information by appropriately adopting the various methods described in <1. Trisoup Point Number Control> and supplies the control information to the bitstream generation unit 305 as described above, the bitstream generation unit 305 can generate a bitstream including the control information generated by appropriately adopting the various methods described in <1. Trisoup Point Number Control>. Accordingly, the encoding device 300 can control the number of the points in the point cloud to be obtained by decoding encoded data. That is, when the points in a point cloud are expressed as a plane and are encoded, the number of the points in the point cloud to be obtained by decoding the encoded data can be controlled.

Furthermore, as the point number determination unit 334 determines whether or not the number of the restored points satisfies a predetermined condition, the sampling interval setting unit 335 can set control information so as to satisfy the condition. Accordingly, the encoding device 300 can perform control so that the number of the points in the point cloud to be obtained by decoding encoded data satisfies the predetermined condition. For example, the encoding device 300 can control the number of the points in the point cloud to be obtained by decoding encoded data, so as to comply with restrictions regarding profiles and levels.

<Flow in an Encoding Process>

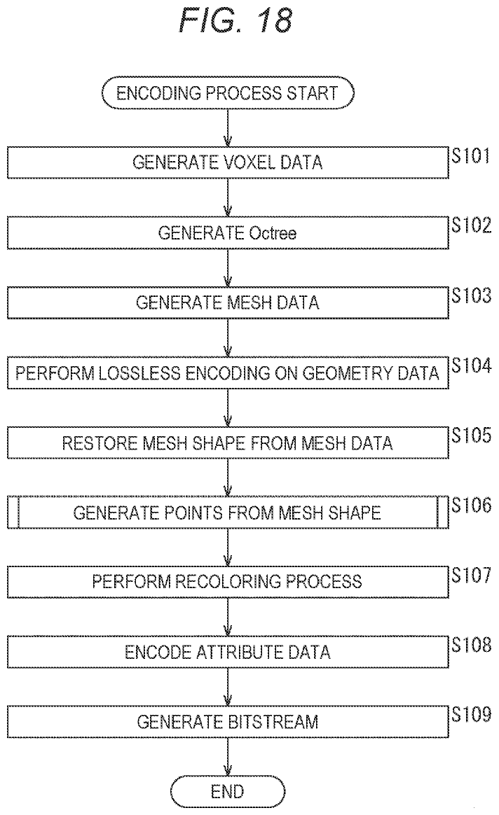

Next, an example flow in an encoding process to be performed by the encoding device 300 is described, with reference to a flowchart shown in FIG. 18.

When an encoding process is started, the voxel generation unit 301 generates voxel data using point cloud data in step S101.

In step S102, the octree generation unit 311 constructs an octree using the voxel data, and generates octree data.

In step S103, the mesh generation unit 312 generates trisoup data (also referred to as mesh data), on the basis of the octree data.

In step S104, the lossless encoding unit 313 performs lossless encoding on geometry data including the octree data generated in step S102 and the trisoup data generated in step S103, to generate encoded data of the geometry data.

In step S105, the mesh shape restoration unit 321 restores a mesh shape (or a triangular plane) from the trisoup data (mesh data) included in the geometry data.

In step S106, the point generation unit 322 performs a point generation process, to generate (restore) points from the restored mesh shape. In doing so, the point generation unit 322 generates points by appropriately adopting the various methods described in <1. Trisoup Point Number Control>, and further generates control information (sampling information and the like) for controlling the number of the points to be restored in the decoding.

In step S107, the recoloring processing unit 323 performs a recoloring process, to match the attribute data with the geometry data from which the points have been restored.

In step S108, the attribute information encoding unit 304 encodes the attribute data using the geometry data, to generate encoded data of the attribute data.

In step S109, the bitstream generation unit 305 generates a bitstream including the encoded data of the geometry data generated in step S104, the encoded data of the attribute data generated in step S108, and the control information generated in step S106. The bitstream generation unit 305 then outputs the generated bitstream to the outside of the encoding device 500.

When the process in step S109 is completed, the encoding process comes to an end.

By performing the respective processes as described above, the encoding device 300 can control the number of the points in the point cloud to be obtained by decoding encoded data. That is, when the points in a point cloud are expressed as a plane and are encoded, the number of the points in the point cloud to be obtained by decoding the encoded data can be controlled.

<Flow in the Point Generation Process>

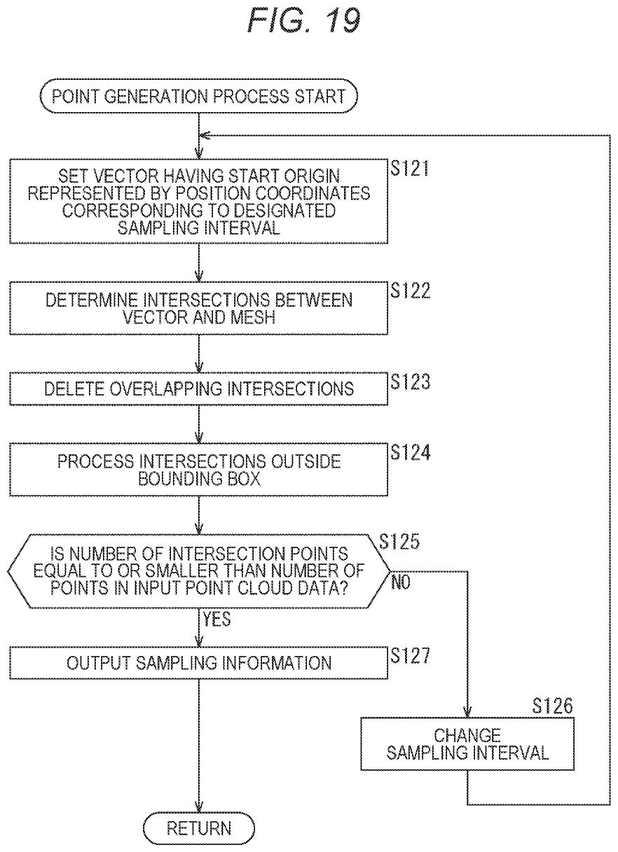

Next, an example flow in the point generation process to be performed in step S106 in FIG. 18 is described, with reference to a flowchart shown in FIG. 19.

When the point generation process is started, the vector setting unit 331 in step S121 sets vectors Vi having start origins at the position coordinates corresponding to the sampling interval designated by the sampling information generated by the sampling interval setting unit 335.

In step S122, the intersection determination unit 332 determines the intersections between the vectors and a triangular plane (mesh).

In step S123, the auxiliary processing unit 333 deletes the intersections whose positions overlap (or deletes the overlaps) among the intersections derived in step S122.

In step S124, the auxiliary processing unit 333 processes the intersections outside the bounding box. For example, the auxiliary processing unit 333 can delete the intersections located outside the bounding box. The auxiliary processing unit 333 can also move the intersections located outside the bounding box into the bounding box by a clip process.

In step S125, the point number determination unit 334 determines whether or not the number of the intersection points is equal to or smaller than the number of the points in input point cloud data. That is, a predetermined condition herein is that “the number of the intersection points is equal to or smaller than the number of the points in the point cloud data that is input to the encoding device 300”. If the number of the intersection points after the auxiliary processing is determined to be larger than the number of the points in the input point cloud data, the process moves on to step S126.

In step S126, the sampling interval setting unit 335 changes the sampling interval (or updates the sampling information) so that the number of the intersection points after the auxiliary processing becomes equal to or smaller than the number of the points in the input point cloud data. In doing so, the sampling interval setting unit 335 generates points by appropriately adopting the various methods described in <1. Trisoup Point Number Control>, and further generates control information (sampling information and the like) for controlling the number of the points to be restored in the decoding.

When the process in step S126 is completed, the process returns to step S121. That is, the processes in steps S121 to S125 are repeated using the updated sampling information.

If the number of the intersection points after the auxiliary processing is determined to be equal to or smaller than the number of the points in the input point cloud data in step S125, the process moves on to step S127.

In step S127, the sampling interval setting unit 335 supplies the current sampling information to the bitstream generation unit 305, and causes the bitstream generation unit 305 to output a bitstream including the sampling information.

When the process in step S127 is completed, the point generation process comes to an end, and the process returns to FIG. 18.

By performing the respective processes as described above, the bitstream generation unit 305 can generate a bitstream including the control information generated by appropriately adopting the various methods described in <1. Trisoup Point Number Control>. Accordingly, the encoding device 300 can control the number of the points in the point cloud to be obtained by decoding encoded data. That is, when the points in a point cloud are expressed as a plane and are encoded, the number of the points in the point cloud to be obtained by decoding the encoded data can be controlled.

### 3. SECOND EMBODIMENT

<Decoding Device>

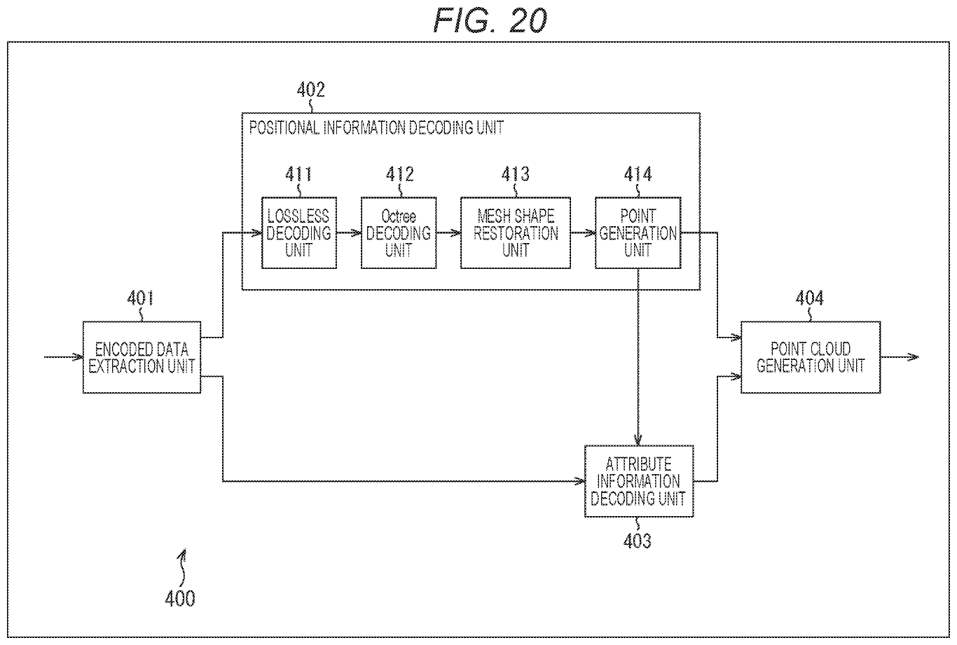

FIG. 20 is a block diagram showing an example configuration of a decoding device as an embodiment of an image processing apparatus to which the present technology is applied. A decoding device 400 shown in FIG. 20 is a device that decodes encoded data of 3D data such as a point cloud. In this decoding, the decoding device 400 decodes encoded data generated by encoding a point cloud by a technique such as voxel, octree, or trisoup. Also, at the time of the decoding, the decoding device 400 decodes encoded data in accordance with control information for controlling the number of the points in the point cloud to be obtained by decoding the encoded data, as described above in <1. Trisoup Point Number Control>. For example, the decoding device 400 decodes encoded data of a trisoup, on the basis of control information for controlling the number of the points to be derived from the triangular plane of the trisoup, the control information being included in a bitstream.

The decoding device 400 corresponds to the encoding device 300, for example, and can decode a bitstream generated by the encoding device 300 (a bitstream generated as described in the first embodiment).

Note that FIG. 20 shows the principal components and aspects such as processing units and a data flow, but FIG. 20 does not necessarily show all the components and aspects. That is, in the decoding device 400, there may be a processing unit that is not shown as a block in FIG. 20, or there may be processing or a data flow that is not indicated by arrows or the like in FIG. 20. This also applies to the other drawings for explaining the processing units and the like in the decoding device 400.

As shown in FIG. 20, the decoding device 400 includes an encoded data extraction unit 401, a positional information decoding unit 402, an attribute information decoding unit 403, and a point cloud generation unit 404.

The encoded data extraction unit 401 performs a process related to extraction of encoded data from a bitstream. For example, the encoded data extraction unit 401 can acquire a bitstream to be decoded. The encoded data extraction unit 401 can also extract the encoded data of geometry data and attribute data included in the acquired bitstream.

The encoded data extraction unit 401 can also supply the extracted encoded data of the geometry data to the positional information decoding unit 402. Further, the encoded data extraction unit 401 can supply the extracted encoded data of the attribute data to the attribute information decoding unit 403.

The positional information decoding unit 402 performs a process related to decoding of encoded data of geometry data. For example, the positional information decoding unit 402 can acquire the encoded data of the geometry data supplied from the encoded data extraction unit 401. The positional information decoding unit 402 can also decode the acquired encoded data of the geometry data, to generate the geometry data. Further, the positional information decoding unit 402 can supply the generated geometry data to the point cloud generation unit 404. The positional information decoding unit 402 can also supply the generated geometry data to the attribute information decoding unit 403.

The attribute information decoding unit 403 performs a process related to decoding of encoded data of attribute data. For example, the attribute information decoding unit 403 can acquire the encoded data of the attribute data supplied from the encoded data extraction unit 401. The attribute information decoding unit 403 can also acquire the geometry data supplied from the positional information decoding unit 402 (a point generation unit 414).

Further, using the acquired geometry data, the attribute information decoding unit 403 can decode the acquired encoded data of the attribute data, to generate the attribute data. The attribute information decoding unit 403 can also supply the generated attribute data to the point cloud generation unit 404.

The point cloud generation unit 404 performs a process related to generation of point cloud data. For example, the point cloud generation unit 404 can acquire the geometry data supplied from the positional information decoding unit 402. The point cloud generation unit 404 can also acquire the attribute data supplied from the attribute information decoding unit 403. Further, the point cloud generation unit 404 can generate point cloud data, using the acquired geometry data and attribute data. The point cloud generation unit 404 can also output the generated point cloud data to the outside of the decoding device 400.

Further, as shown in FIG. 20, the positional information decoding unit 402 includes a lossless decoding unit 411, an octree decoding unit 412, a mesh shape restoration unit 413, and a point generation unit 414.

The lossless decoding unit 411 performs a process related to lossless decoding of encoded data of geometry data. For example, the lossless decoding unit 411 can acquire the encoded data of the geometry data supplied from the encoded data extraction unit 401. This encoded data is the geometry data subjected to lossless encoding. The lossless decoding unit 411 can generate the geometry data by performing lossless decoding on the encoded data of the geometry data by a lossless decoding method compatible with the lossless encoding unit 313. The lossless decoding unit 411 can also supply the geometry data (including octree data and trisoup data) generated by performing lossless decoding on the encoded data, to the octree decoding unit 412. Note that this trisoup data includes control information (sampling information, for example) for controlling the number of the points to be restored in the decoding.

The octree decoding unit 412 performs a process related to decoding of octree data. For example, the octree decoding unit 412 can acquire the geometry data supplied from the lossless decoding unit 411. The octree decoding unit 412 can also generate voxel data from the octree data included in the geometry data. Further, the octree decoding unit 412 can supply geometry data including the generated voxel data and the trisoup data to the mesh shape restoration unit 413.

The mesh shape restoration unit 413 performs a process related to restoration of a triangular plane (mesh). For example, the mesh shape restoration unit 413 can acquire geometry data that is the voxel data and the trisoup data supplied from the octree decoding unit 412. The mesh shape restoration unit 413 can also restore the triangular plane (mesh), using the trisoup data. Further, the mesh shape restoration unit 413 can supply the geometry data having the restored triangular plane to the point generation unit 414. Note that this geometry data includes the control information (sampling information, for example) for controlling the number of the points to be restored in the decoding.

The point generation unit 414 performs a process related to generation (restoration) of points. For example, the point generation unit 414 can acquire the geometry data with the restored triangular plane supplied from the mesh shape restoration unit 413. The point generation unit 414 can also generate (restore) points from the triangular plane, on the basis of the control information (sampling information, for example) for controlling the number of the points to be restored in the decoding, the control information being included in the geometry data.

This control information is information generated by appropriately adopting the various methods described in <1. Trisoup Point Number Control>. Accordingly, by restoring points in accordance with this control information, the point generation unit 414 can restore the number of points in accordance with the control at the encoding side.

Further, the point generation unit 414 can supply the geometry data in which the points have been restored in the above manner, to the point cloud generation unit 404.

For example, when all the points in a point cloud having the highest resolution are represented by a triangular plane and are encoded, the point generation unit 414 can restore the points from the triangular plane as described above, and supply the geometry data of all the restored points as a decoding result to the point cloud generation unit 404.

Note that each of these processing units (from the encoded data extraction unit 401 to the point cloud generation unit 404) of the decoding device 400 has any appropriate configuration. For example, each processing unit may be formed with a logic circuit that performs the processes described above. Alternatively, each processing unit may also include a CPU, ROM, RAM, and the like, for example, and execute a program using them, to perform the processes described above. Each processing unit may of course have both configurations, and perform some of the processes described above with a logic circuit, and the other by executing a program. The configurations of the respective processing units may be independent of one another. For example, one processing unit may perform some of the processes described above with a logic circuit while the other processing units perform the processes described above by executing a program. Further, some other processing unit may perform the processes described above both with a logic circuit and by executing a program.

As described above, the lossless decoding unit 411 decodes the encoded data of the geometry data, and the point generation unit 414 restores the points in accordance with the control information. Thus, the decoding device 400 can derive the points from the trisoup data in accordance with the control at the encoding side. That is, the encoding side can control the number of the points in the point cloud to be obtained by decoding encoded data.

<Point Generation Unit>

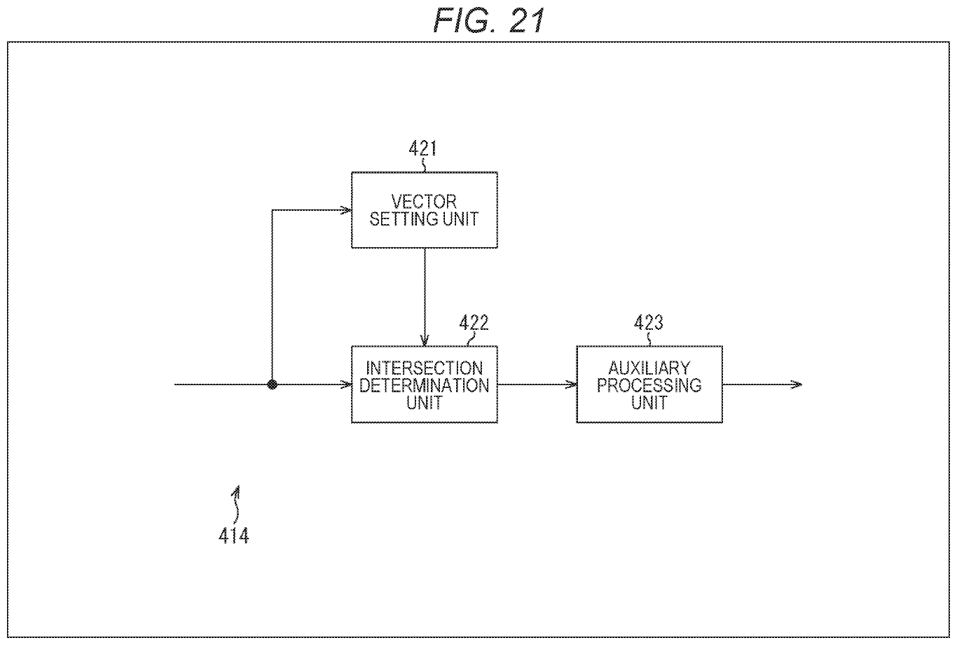

FIG. 21 is a block diagram showing a typical example configuration of the point generation unit 414. As shown in FIG. 21, the point generation unit 414 includes a vector setting unit 421, an intersection determination unit 422, and an auxiliary processing unit 423.

The vector setting unit 421 performs a process related to setting of the vectors Vi. For example, the vector setting unit 421 can acquire the geometry data supplied from the mesh shape restoration unit 413. The vector setting unit 421 can also set the vectors Vi for the triangular plane of the geometry data, on the basis of the control information included in the geometry data. That is, the vector setting unit 421 can set the vectors Vi in accordance with the control at the encoding side. The vector setting unit 421 can supply the set vectors Vi to the intersection determination unit 422.

The intersection determination unit 422 performs a process related to determination of the intersections between the vectors Vi and a triangular plane. For example, the intersection determination unit 422 can acquire the geometry data supplied from the mesh shape restoration unit 413. The intersection determination unit 422 can also acquire the vectors Vi supplied from the vector setting unit 421. Further, the intersection determination unit 422 can compare them, and obtain the intersections between the triangular plane included in the geometry data and the vectors Vi (or derive intersection coordinates). The intersection determination unit 422 can also supply the derived intersection coordinates to the auxiliary processing unit 423.

The auxiliary processing unit 423 performs auxiliary processing on the intersections. For example, the auxiliary processing unit 423 can acquire the intersection coordinates supplied from the intersection determination unit 422. The auxiliary processing unit 423 can also perform predetermined auxiliary processing on the acquired intersection coordinates.

For example, when the coordinate values of the intersections overlap between different vectors or in the triangular plane, the auxiliary processing unit 423 may delete intersections except for one. By deleting the overlapping points in this manner, it is possible to reduce the increase in unnecessary processing, and reduce the increase in load (for example, processing can be performed at higher speed). Further, when the coordinate values of the intersections are outside the bounding box, the auxiliary processing unit 423 may clip (move) the positions of the intersections into the bounding box by a clip process. Alternatively, the intersections may be deleted.

The auxiliary processing unit 423 can supply the point cloud generation unit 404 with the intersection coordinates subjected to the auxiliary processing as a result of decoding of the geometry data. The auxiliary processing unit 423 can also supply this decoding result to the attribute information decoding unit 403.

As the vector setting unit 421 sets the vectors Vi in accordance with the control information (the control at the encoding side) as described above, the decoding device 400 can derive points from the trisoup data in accordance with the control at the encoding side. That is, the encoding side can control the number of the points in the point cloud to be obtained by decoding encoded data.

<Flow in a Decoding Process>

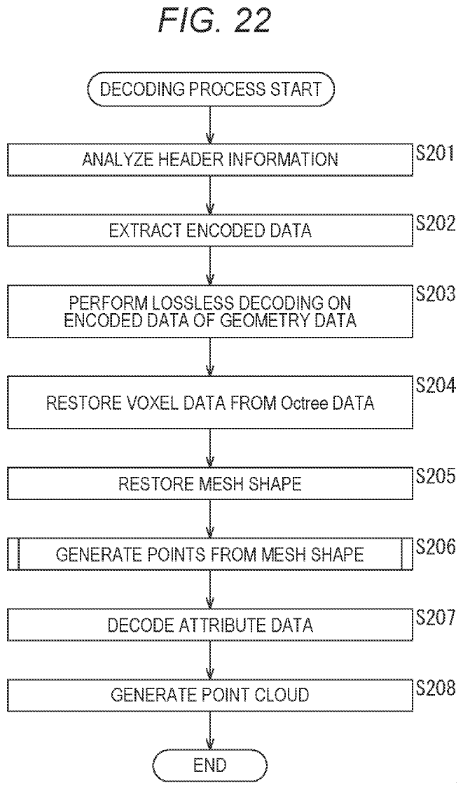

Next, an example flow in a decoding process to be performed by the decoding device 400 is described with reference to a flowchart shown in FIG. 22.

When a decoding process is started, the encoded data extraction unit 401 analyzes the header information included in a bitstream in step S201. In step S202, the encoded data extraction unit 401 also extracts encoded data of geometry data and encoded data of attribute data from the bitstream.

In step S203, the lossless decoding unit 411 performs lossless decoding on the encoded data of the geometry data extracted in step S203, to generate geometry data including octree data and trisoup data.

In step S204, the octree decoding unit 412 restores voxel data from the octree data included in the geometry data.

In step S205, the mesh shape restoration unit 413 restores a mesh shape (a triangular plane) from the voxel data restored in step S204.

In step S206, the point generation unit 414 performs a point generation process, to generate (restore) points from the mesh shape (the triangular plane) restored in step S205.

In step S207, the attribute information decoding unit 403 decodes the attribute data.

In step S208, the point cloud generation unit 404 generates point cloud data, using the geometry data generated in step S206 and the attribute data generated in step S207.

When the process in step S208 is completed, the decoding process comes to an end.

By performing the respective processes as above, the decoding device 400 can derive points from the trisoup data in accordance with the control at the encoding side. That is, the encoding side can control the number of the points in the point cloud to be obtained by decoding encoded data.

<Flow in the Point Generation Process>

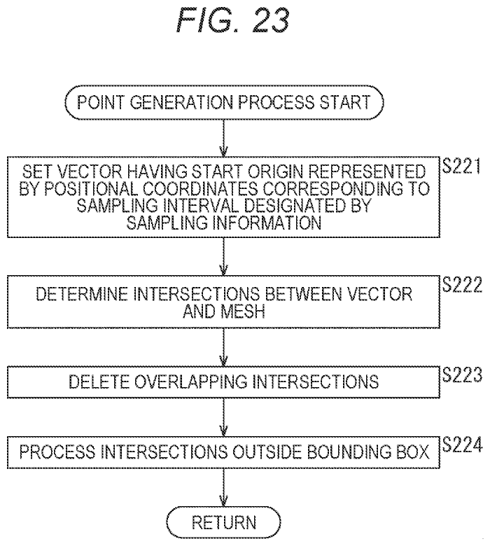

Next, an example flow in the point generation process to be performed in step S206 in FIG. 22 is described, with reference to a flowchart shown in FIG. 23.

When the point generation process is started, the vector setting unit 421 in step S221 sets vectors Vi having start origins at the position coordinates corresponding to the sampling interval designated by the sampling information (control information) included in the encoded data.

In step S222, the intersection determination unit 422 determines the intersections between the mesh (the triangular plane) in the geometry data and the vectors Vi set in step S221 (or derives intersection coordinates).

In step S223, the auxiliary processing unit 423 performs auxiliary processing, to delete the overlapping intersections (or eliminate the overlaps among the intersections). In step S224, the auxiliary processing unit 423 performs auxiliary processing, to process the intersections outside the bounding box. For example, the auxiliary processing unit 423 can delete the intersections located outside the bounding box. The auxiliary processing unit 423 can also move the intersections located outside the bounding box into the bounding box by a clip process.

When the process in step S223 is completed, the point generation process comes to an end, and the process returns to FIG. 22.

By performing the respective processes as above, the decoding device 400 can derive points from the trisoup data in accordance with the control at the encoding side. That is, the encoding side can control the number of the points in the point cloud to be obtained by decoding encoded data.

### 4. THIRD EMBODIMENT

<Flow in the Point Generation Process>

In the example of the point generation process described above with reference to the flowchart in FIG. 19, the predetermined condition is that “the number of restored points is equal to or smaller than the number of the points in point cloud data that is input to the encoding device 300”, and the point number determination unit 334 determines whether or not the number of restored points satisfies the predetermined condition.

The predetermined condition may be any appropriate condition, and is not limited to this example. For example, the predetermined condition may be that “the number of restored points is equal to or smaller than a predetermined maximum number of points that is larger than the number of the points in the point cloud data input to the encoding device 300”. For example, the upper limit value of the number of points to be designed by the profile or the level may be set at a greater value than the number of the points in the point cloud data that is input to the encoding device 300, and control may be performed so that the number of restored points does not exceed the upper limit value.

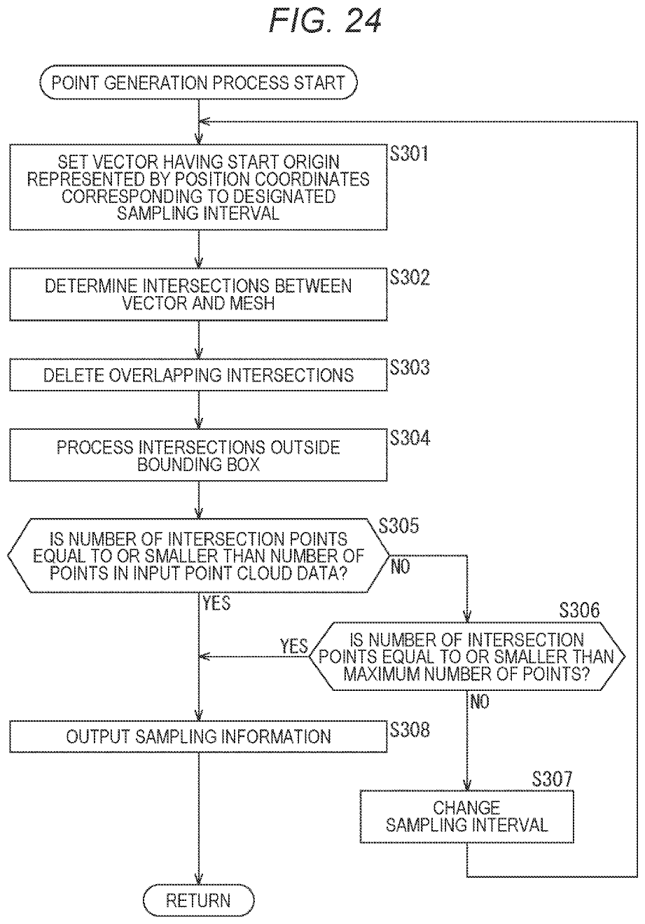

An example flow in the point generation process to be performed by the encoding device 300 in that case is described with reference to a flowchart shown in FIG. 24. Note that this point generation process corresponds to the flowchart shown in FIG. 19.

When the point generation process is started, the respective processes in steps S301 to S305 are performed in a manner similar to the respective processes in steps S121 to S125 in FIG. 19.

If the number of the intersection points after the auxiliary processing is determined to be larger than the number of the points in the input point cloud data in step S305, the process moves on to step S306.

In step S306, the point number determination unit 334 determines whether or not the number of the intersection points is equal to or smaller than a preset maximum point number (a maximum point number designated by the profile or the level, for example). If the number of the intersection points after the auxiliary processing is determined to be larger than this maximum point number, the process moves on to step S307.

The process in step S307 is performed in a manner similar to that in step S126 in FIG. 19. When the process in step S307 is completed, the process returns to step S301. That is, the processes in steps S301 to S305 (S306) are repeated using the updated sampling information.

If the number of the intersection points after the auxiliary processing is determined to be equal to or smaller than the preset maximum point number in step S306, the process moves on to step S308.

If the number of the intersection points after the auxiliary processing is determined to be equal to or smaller than the number of the points in the input point cloud data in step S305, on the other hand, the process moves on to step S308.

The process in step S308 is performed in a manner similar to that in step S127 in FIG. 19. When the process in step S308 is completed, the point generation process comes to an end, and the process returns to FIG. 18.

By performing the respective processes as described above, the bitstream generation unit 305 can generate a bitstream including the control information generated by appropriately adopting the various methods described in <1. Trisoup Point Number Control>, as in the case of FIG. 19. Accordingly, the encoding device 300 can control the number of the points in the point cloud to be obtained by decoding encoded data. That is, when the points in a point cloud are expressed as a plane and are encoded, the number of the points in the point cloud to be obtained by decoding the encoded data can be controlled.

### 5. NOTES

<Transmission of a Control Flag>

A control flag according to the present technology described in each of the above embodiments may be transmitted from the encoding side to the decoding side. For example, a control flag (enabled_flag, for example) for controlling whether or not to allow (or prohibit) application of the present technology described above may be transmitted.

<Computer>

The above described series of processes can be performed by hardware or can be performed by software. When the series of processes are to be performed by software, the program that forms the software is installed into a computer. Here, the computer may be a computer incorporated into special-purpose hardware, or may be a general-purpose personal computer or the like that can execute various kinds of functions when various kinds of programs are installed thereinto, for example.

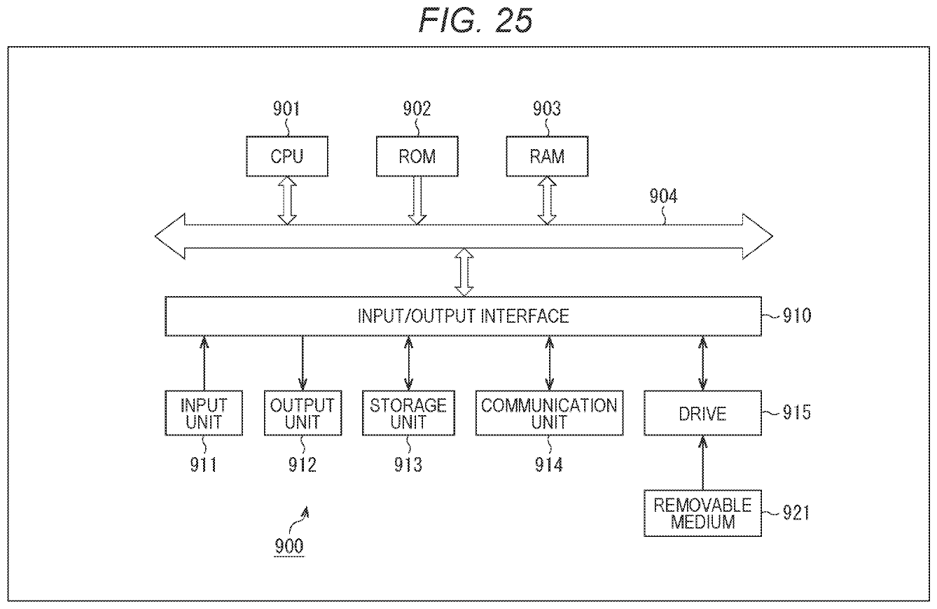

FIG. 25 is a block diagram showing an example configuration of the hardware of a computer that performs the above described series of processes in accordance with a program.

In a computer 900 shown in FIG. 25, a central processing unit (CPU) 901, a read only memory (ROM) 902, and a random access memory (RAM) 903 are connected to one another by a bus 904.

An input/output interface 910 is also connected to the bus 904. An input unit 911, an output unit 912, a storage unit 913, a communication unit 914, and a drive 915 are connected to the input/output interface 910.

The input unit 911 is formed with a keyboard, a mouse, a microphone, a touch panel, an input terminal, and the like, for example. The output unit 912 is formed with a display, a speaker, an output terminal, and the like, for example. The storage unit 913 is formed with a hard disk, a RAM disk, a nonvolatile memory, and the like, for example. The communication unit 914 is formed with a network interface, for example. The drive 915 drives a removable medium 921 such as a magnetic disk, an optical disk, a magnetooptical disk, or a semiconductor memory.

In the computer having the above described configuration, the CPU 901 loads a program stored in the storage unit 913 into the RAM 903 via the input/output interface 910 and the bus 904, for example, and executes the program, so that the above described series of processes is performed. The RAM 903 also stores data necessary for the CPU 901 to perform various processes and the like as necessary.

The program to be executed by the computer may be recorded on the removable medium 921 as a packaged medium or the like to be used, for example. In that case, the program can be installed into the storage unit 913 via the input/output interface 910 when the removable medium 921 is mounted on the drive 915.

Alternatively, this program can be provided via a wired or wireless transmission medium such as a local area network, the Internet, or digital satellite broadcasting. In that case, the program may be received by the communication unit 914, and be installed into the storage unit 913.

Also, this program may be installed beforehand into the ROM 902 or the storage unit 913.

<Targets to which the Present Technology is Applied>

Although cases where the present technology is applied to encoding and decoding of point cloud data have been described so far, the present technology is not limited to those examples, but can be applied to encoding and decoding of 3D data of any standard. That is, various processes such as encoding and decoding processes, and any specifications of various kinds of data such as 3D data and metadata can be adopted, as long as the present technology described above is not contradicted. Also, some of the processes and specifications described above may be omitted, as long as the present technology is not contradicted.

Further, in the above description, the encoding device 300 and the decoding device 400 have been described as example applications of the present technology, but the present technology can be applied to any desired configuration.

For example, the present technology can be applied to various electronic apparatuses, such as transmitters and receivers (television receivers or portable telephone devices, for example) in satellite broadcasting, cable broadcasting such as cable TV, distribution via the Internet, distribution to terminals via cellular communication, or the like, and apparatuses (hard disk recorders or cameras, for example) that record images on media such as optical disks, magnetic disks, and flash memory, and reproduce images from these storage media, for example.

Further, the present technology can also be embodied as a component of an apparatus, such as a processor (a video processor, for example) serving as a system LSI (Large Scale Integration) or the like, a module (a video module, for example) using a plurality of processors or the like, a unit (a video unit, for example) using a plurality of modules or the like, or a set (a video set, for example) having other functions added to units.

Further, the present technology can also be applied to a network system formed with a plurality of devices, for example. For example, the present technology may be embodied as cloud computing that is shared and jointly processed by a plurality of devices via a network. For example, the present technology may be embodied in a cloud service that provides services related to images (video images) to any kinds of terminals such as computers, audio visual (AV) devices, portable information processing terminals, and IoT (Internet of Things) devices.

Note that, in the present specification, a system means an assembly of plurality of components (devices, modules (parts), and the like), and not all the components need to be provided in the same housing. In view of this, plurality of devices that are housed in different housings and are connected to one another via a network form a system, and one device having plurality of modules housed in one housing is also a system.

<Fields and Usage to which the Present Technology can be Applied>

A system, an apparatus, a processing unit, and the like to which the present technology is applied can be used in any appropriate field such as transportation, medical care, crime prevention, agriculture, the livestock industry, mining, beauty care, factories, household appliances, meteorology, or nature observation, for example. The present technology can also be used for any appropriate purpose.

### OTHER ASPECTS

Note that, in this specification, a “flag” is information for identifying a plurality of states, and includes not only information to be used for identifying two states of true (1) or false (0), but also information for identifying three or more states. Therefore, the values this “flag” can have may be the two values of “1” and “0”, for example, or three or more values. That is, this “flag” may be formed with any number of bits, and may be formed with one bit or a plurality of bits. Further, as for identification information (including a flag), not only the identification information but also difference information about the identification information with respect to reference information may be included in a bitstream. Therefore, in this specification, a “flag” and “identification information” include not only the information but also difference information with respect to the reference information.

Further, various kinds of information (such as metadata) regarding encoded data (a bitstream) may be transmitted or recorded in any mode that is associated with the encoded data. Here, the term “to associate” means to enable use of other data (or a link to other data) while data is processed, for example. That is, pieces of data associated with each other may be integrated as one piece of data, or may be regarded as separate pieces of data. For example, information associated with encoded data (an image) may be transmitted through a transmission path different from that for the encoded data (image). Further, information associated with encoded data (an image) may be recorded in a recording medium different from that for the encoded data (image) (or in a different recording area of the same recording medium), for example. Note that this “association” may apply to part of the data, instead of the entire data. For example, an image and the information corresponding to the image may be associated with each other for any appropriate unit, such as for a plurality of frames, each frame, or some portion in each frame.

Note that, in this specification, the terms “to combine”, “to multiplex”, “to add”, “to integrate”, “to include”, “to store”, “to contain”, “to incorporate, “to insert”, and the like mean combining a plurality of objects into one, such as combining encoded data and metadata into one piece of data, for example, and mean a method of the above described “association”.

Further, embodiments of the present technology are not limited to the above described embodiments, and various modifications may be made to them without departing from the scope of the present technology.

For example, any configuration described above as one device (or one processing unit) may be divided into a plurality of devices (or processing units). Conversely, any configuration described above as a plurality of devices (or processing units) may be combined into one device (or one processing unit). Furthermore, it is of course possible to add a component other than those described above to the configuration of each device (or each processing unit). Further, some components of a device (or processing unit) may be incorporated into the configuration of another device (or processing unit) as long as the configuration and the functions of the entire system remain substantially the same.

Also, the program described above may be executed in any device, for example. In that case, the device is only required to have necessary functions (function blocks and the like) so that necessary information can be obtained.

Also, one device may carry out each step in one flowchart, or a plurality of devices may carry out each step, for example. Further, when one step includes a plurality of processes, the plurality of processes may be performed by one device or may be performed by a plurality of devices. In other words, a plurality of processes included in one step may be performed as processes in a plurality of steps. Conversely, processes described as a plurality of steps may be collectively performed as one step.

Also, a program to be executed by a computer may be a program for performing the processes in the steps according to the program in chronological order in accordance with the sequence described in this specification, or may be a program for performing processes in parallel or performing a process when necessary, such as when there is a call, for example. That is, as long as there are no contradictions, the processes in the respective steps may be performed in a different order from the above described order. Further, the processes in the steps according to this program may be executed in parallel with the processes according to another program, or may be executed in combination with the processes according to another program.

Also, each of the plurality of techniques according to the present technology can be independently implemented, as long as there are no contradictions, for example. It is of course also possible to implement a combination of some of the plurality of techniques according to the present technology. For example, part or all of the present technology described in one of the embodiments may be implemented in combination with part or all of the present technology described in another one of the embodiments. Further, part or all of the present technology described above may be implemented in combination with some other technology not described above.

Note that the present technology may also be embodied in the configurations described below.

(1) An information processing apparatus including

a generation unit that generates a bitstream that includes encoded data of 3D data having a plane expressing points in a point cloud that expresses a three-dimensional object as a set of the points, and control information for controlling the number of the points to be derived from the 3D data to be obtained by decoding the encoded data.

(2) The information processing apparatus according to (1), in which

the 3D data includes data that includes vertex coordinates of a triangular plane, and expresses the points as the triangular plane.

(3) The information processing apparatus according to (2), in which

the points are derived as intersecting points between the triangular plane and vectors in three axial directions perpendicular to one another.

(4) The information processing apparatus according to (3), in which

the control information includes sampling information for designating an interval between the vectors.

(5) The information processing apparatus according to (4), in which

the sampling information designates the interval between the vectors with an integer value.

(6) The information processing apparatus according to (4) or (5), in which

the sampling information designates the interval between the vectors independently for each direction of the vectors.

(7) The information processing apparatus according to any one of (1) to (6), further including

a setting unit that sets the control information,

in which the generation unit generates the bitstream including the encoded data of the 3D data, and the control information set by the setting unit.

(8) The information processing apparatus according to (7), in which

the setting unit sets the control information to limit the number of the points to be derived from the 3D data to a number that is equal to or smaller than an upper limit value that depends on a profile or a level.

(9) The information processing apparatus according to (7), in which

the setting unit sets the control information to limit the number of the points to be derived from the 3D data to a number that is equal to or smaller than the number of the points in the point cloud before encoding.

(10) An information processing method including

generating a bitstream that includes encoded data of 3D data having a plane expressing points in a point cloud that expresses a three-dimensional object as a set of the points, and control information for controlling the number of the points to be derived from the 3D data to be obtained by decoding the encoded data.

(11) An information processing apparatus including:

a decoding unit that decodes a bitstream, to generate 3D data having a plane expressing points in a point cloud that expresses a three-dimensional object as a set of the points, and control information for controlling the number of the points to be derived from the 3D data; and

a derivation unit that derives the points from the 3D data, on the basis of the control information.

(12) The information processing apparatus according to (11), in which

the 3D data includes data that includes vertex coordinates of a triangular plane, and expresses the points as the triangular plane, and

the derivation unit derives the points, using the triangular plane indicated by the vertex coordinates.

(13) The information processing apparatus according to (12), in which

the derivation unit derives the points as intersections between the triangular plane and vectors in three axial directions perpendicular to one another.

(14) The information processing apparatus according to (13), in which

the control information includes sampling information for designating an interval between the vectors, and

the derivation unit derives the points as intersections between the triangular plane and the vectors at the interval designated by the sampling information.

(15) The information processing apparatus according to (14), in which

the sampling information includes information for designating the interval between the vectors with an integer value.

(16) The information processing apparatus according to (14) or (15), in which

the sampling information includes information for designating the interval between the vectors independently for each direction of the vectors.

(17) The information processing apparatus according to any one of (14) to (16), in which

the sampling information includes information for designating the interval between the vectors for each slice.

(18) The information processing apparatus according to (17), in which

the sampling information is stored in data of each slice in the bitstream.

(19) The information processing apparatus according to (17), in which

the sampling information is stored in a parameter set of geometry data in the bitstream.

(20) An information processing method including:

decoding a bitstream, to generate 3D data having a plane expressing points in a point cloud that expresses a three-dimensional object as a set of the points, and control information for controlling the number of the points to be derived from the 3D data; and

deriving the points from the 3D data, on the basis of the control information.

### REFERENCE SIGNS LIST

300 Encoding device
301 Voxel generation unit
302 Positional information encoding unit
303 Positional information decoding unit
304 Attribute information encoding unit
305 Bitstream generation unit
311 Octree generation unit
312 Mesh generation unit
313 Lossless encoding unit
321 Mesh shape restoration unit
322 Point generation unit
323 Recoloring processing unit
331 Vector setting unit
332 Intersection determination unit
333 Auxiliary processing unit
334 Point number determination unit
335 Sampling interval setting unit
400 Decoding device
401 Encoded data extraction unit
402 Positional information decoding unit
403 Attribute information decoding unit
404 Point cloud generation unit
411 Lossless decoding unit
412 Octree decoding unit
413 Mesh shape restoration unit
414 Point generation unit
421 Vector setting unit
422 Intersection determination unit
423 Auxiliary processing unit

1. An information processing apparatus comprising
a generation unit that generates a bitstream that includes encoded data of 3D data having a plane expressing points in a point cloud that expresses a three-dimensional object as a set of the points, and control information for controlling the number of the points to be derived from the 3D data to be obtained by decoding the encoded data.

2. The information processing apparatus according to claim 1, wherein
the 3D data includes data that includes vertex coordinates of a triangular plane, and expresses the points as the triangular plane.

3. The information processing apparatus according to claim 2, wherein
the points are derived as intersecting points between the triangular plane and vectors in three axial directions perpendicular to one another.

4. The information processing apparatus according to claim 3, wherein
the control information includes sampling information for designating an interval between the vectors.

5. The information processing apparatus according to claim 4, wherein
the sampling information designates the interval between the vectors with an integer value.

6. The information processing apparatus according to claim 4, wherein
the sampling information designates the interval between the vectors independently for each direction of the vectors.

7. The information processing apparatus according to claim 1, further comprising
a setting unit that sets the control information,
wherein the generation unit generates the bitstream including the encoded data of the 3D data, and the control information set by the setting unit.

8. The information processing apparatus according to claim 7, wherein
the setting unit sets the control information to limit the number of the points to be derived from the 3D data to a number that is equal to or smaller than an upper limit value that depends on a profile or a level.

9. The information processing apparatus according to claim 7, wherein
the setting unit sets the control information to limit the number of the points to be derived from the 3D data to a number that is equal to or smaller than the number of the points in the point cloud before encoding.

10. An information processing method comprising
generating a bitstream that includes encoded data of 3D data having a plane expressing points in a point cloud that expresses a three-dimensional object as a set of the points, and control information for controlling the number of the points to be derived from the 3D data to be obtained by decoding the encoded data.

11. An information processing apparatus comprising:
a decoding unit that decodes a bitstream, to generate 3D data having a plane expressing points in a point cloud that expresses a three-dimensional object as a set of the points, and control information for controlling the number of the points to be derived from the 3D data; and
a derivation unit that derives the points from the 3D data, on a basis of the control information.

12. The information processing apparatus according to claim 11, wherein
the 3D data includes data that includes vertex coordinates of a triangular plane, and expresses the points as the triangular plane, and
the derivation unit derives the points, using the triangular plane indicated by the vertex coordinates.

13. The information processing apparatus according to claim 12, wherein
the derivation unit derives the points as intersecting points between the triangular plane and vectors in three axial directions perpendicular to one another.

14. The information processing apparatus according to claim 13, wherein
the control information includes sampling information for designating an interval between the vectors, and
the derivation unit derives the points as intersections between the triangular plane and the vectors at the interval designated by the sampling information.

15. The information processing apparatus according to claim 14, wherein
the sampling information includes information for designating the interval between the vectors with an integer value.

16. The information processing apparatus according to claim 14, wherein
the sampling information includes information for designating the interval between the vectors independently for each direction of the vectors.

17. The information processing apparatus according to claim 14, wherein
the sampling information includes information for designating the interval between the vectors for each slice.

18. The information processing apparatus according to claim 17, wherein
the sampling information is stored in data of each slice in the bitstream.

19. The information processing apparatus according to claim 17, wherein
the sampling information is stored in a parameter set of geometry data in the bitstream.

20. An information processing method comprising:
decoding a bitstream, to generate 3D data having a plane expressing points in a point cloud that expresses a three-dimensional object as a set of the points, and control information for controlling the number of the points to be derived from the 3D data; and
deriving the points from the 3D data, on a basis of the control information.
